(19) United States
(12) Patent Application Publication
(10) Pub. No.: US 2007/0124631 A1
(43) Pub. Date: May 31, 2007

(54) Bit field selection instruction

(76) Inventors: Darrell D. Boggs, Aloha, OR (US); Chad E. Fogg, Hillsboro, OR (US); Gregory M. Thornton, Portland, OR (US); Tyler S. Anderson, Hillsboro, OR (US)

Correspondence Address: Richard Calderwood;Stexar Corp., 20400 NW Amberwood Dr. #100, Beaverton, OR, 97006-7099, US

(21) Appl. No.: 11/400,434

(22) Filed: Apr. 6, 2006

Related U.S. Application Data
(63) Continuation-in-part of application No. 11/270,213, filed on Nov. 8, 2005.

(51) Int. Cl. G01R 31/28

(52) U.S. Cl. 714/724

(57) ABSTRACT

A digital signal processor having a generalized bit field extraction instruction which can be used to perform a bit field selection operation, a rotate left operation, a rotate right operation, a shift left operation, a logical shift right operation, an arithmetic shift right operation, and so forth.

### RELATED APPLICATION

This application is a continuation-in-part of application Ser. No. 11/270,213 “Bit-Wise Operation Followed by Byte-Wise Permutation for Implementing DSP Data Manipulation Instructions” filed Nov. 08, 2005 by Gregory M. Thornton. Both applications are commonly assigned to Stexar Corporation.

### BACKGROUND OF THE INVENTION

1. Technical Field of the Invention

This invention relates generally to programmable microprocessors, and more specifically to instructions for a digital signal processor which use bit-wise and byte-wise data movements to accomplish a variety of data manipulations.

2. Background Art

FIGS. 1-5 illustrate a 128-bit data location, such as a register, treated as storing a variety of data element sizes. In FIG. 1, the register holds sixteen bytes of eight bits each. In FIG. 2, the register holds eight words of sixteen bits each. In FIG. 3, the register holds four doublewords of thirty-two bits each. In FIG. 4, the register holds two quadwords of sixty-four bits each. In FIG. 5, the register holds one hundred twenty-eight single bits. Other data sizes are possible, such as a single octoword of one hundred twenty-eight bits, or thirty-two nibbles of four bits each, and so forth.

The data elements are conventionally addressed from 0 to N−1, where N is the number of data elements. Conventionally, bits within a byte are addressed 0-7 from the least significant bit to the most significant bit, and are shown ordered right to left. In the conventional little-endian data arrangement, the least significant byte within a multi-byte data element is stored at the lowest address and the most significant byte is stored at the highest address. In the less common big-endian data arrangement, the bytes within a multi-byte data element are stored in the opposite order; however, those skilled in the art know how to handle these differences, and the remainder of this disclosure will be in little-endian terms, for simplicity and consistency. In this disclosure, the data elements will be addressed as indicated by the hexadecimal digits shown above the register in the respective figure. The byte positions will be addressed as indicated by the hexadecimal digits shown in FIG. 1. Values shown within data elements are used to indicate the data values stored in those locations, and will typically represent eight-bit values shown in two-digit hexadecimal format 00 through FF.

Microprocessors, microcontrollers, digital signal processors, ASICs, and other programmable digital logic devices are commonly adapted to execute a variety of instruction types, such as addition, subtraction, multiplication, and so forth. One such type of operation is data movement instructions, such as shifts, rotates, and the like. Some data movement instructions are “bit-wise”, meaning that they are capable of moving data on single bit granularity, rather than e.g. byte granularity. Some data movement instructions are “byte-wise”, meaning that they move bytes around but keep the eight bits of any given byte intact, together, and in the same order, as the bytes are moved around. Other data movement instructions operate on larger data elements, such as words, doublewords, or quadwords, and move intact chunks of that size around without reordering the bits within any given chunk.

In general, the wider a shifter or rotator is made, the more complex its logic becomes, and the more time it takes to complete its operation.

Applicant has realized that, by combining byte-wise operations with bit-wise operations, many data manipulation operations can be simplified. Or, more precisely, the hardware required to perform them can be simplified. Additionally, Applicant has realized that a generalized byte-wise data manipulation operation can be used as a powerful, fundamental operation, to implement a wide variety of specific data movement operations upon a variety of element sizes.

### BRIEF DESCRIPTION OF THE DRAWINGS

FIGS. 1-5 show a 128-bit data element considered as 16 bytes, 8 words, 4 doublewords, 2 quadwords, and 128 bits, respectively.

FIG. 6 shows a digital signal processor including a byte permutation instruction execution unit for performing the instructions described above.

FIGS. 7-8 show a permute instruction operating upon byte data and word data, respectively.

FIG. 9 shows an explode instruction operating upon byte data.

FIG. 10 shows a merge instruction operating upon byte data.

FIG. 11 shows a pack instruction operating upon low bytes of word data.

FIG. 12 shows sign bit replication.

FIG. 13 shows an unpack sign extended instruction operating upon low bytes of word data.

FIGS. 14-18 show a shuffle pair instruction operating upon high bytes of word data across 16 partitions, 8 partitions, 4 partitions, 2 partitions, and 1 partition, respectively.

FIGS. 19-22 show a shuffle pair instruction operating upon low words of doubleword data across 8 partitions, 4 partitions, 2 partitions, and 1 partition, respectively.

FIGS. 23-24 show a shuffle pair instruction operating upon high doublewords of quadword data across 2 partitions and 1 partition, respectively.

FIG. 25 shows a shuffle pair instruction operating upon low quadwords across 2 partitions.

FIG. 26 shows a bit field selection instruction operating upon bit data.

FIG. 27 shows how a bit field selection instruction can be implemented using this invention.

FIGS. 28-30 show a rotate left instruction operating upon byte data, word data, and doubleword data, respectively.

FIG. 31 shows an alternate method of implementing a doubleword rotate left instruction.

FIG. 32 shows how a saturating (clipping) pack low instruction can be implemented.

FIG. 33 shows how a shift right signed word instruction can be implemented.

FIG. 34 shows how a shift right signed doubleword instruction can be implemented.

FIG. 35 shows a data path pipeline according to one embodiment of this invention.

FIG. 36 shows the operation of the bit field selection instruction used to perform a bit field extract operation.

FIG. 37 shows the operation of the bit field selection instruction used to perform a rotate right operation (or a rotate left operation with compiler shift count assistance).

FIG. 38 shows the operation of the bit field selection instruction used to perform a shift left operation with compiler shift count assistance.

FIG. 39 shows the operation of the bit field selection instruction used to perform a logical shift right operation.

FIG. 40 shows the operation of the bit field selection instruction used to perform an arithmetic shift right operation after a sign bit copying operation.

FIG. 41 shows the operation of the bit field selection instruction used to perform an arithmetic shift right operation after a sign bit testing operation.

FIG. 42 shows the operation of the bit field selection instruction used to perform a load operation.

FIG. 43 shows the operation of the bit field selection instruction used to perform a shift left operation with hardware shift count assistance.

FIG. 44 shows the operation of the bit field selection instruction used to perform a rotate left operation with hardware shift count assistance.

FIG. 45 shows the operation of a SIMD implementation of the bit field selection instruction.

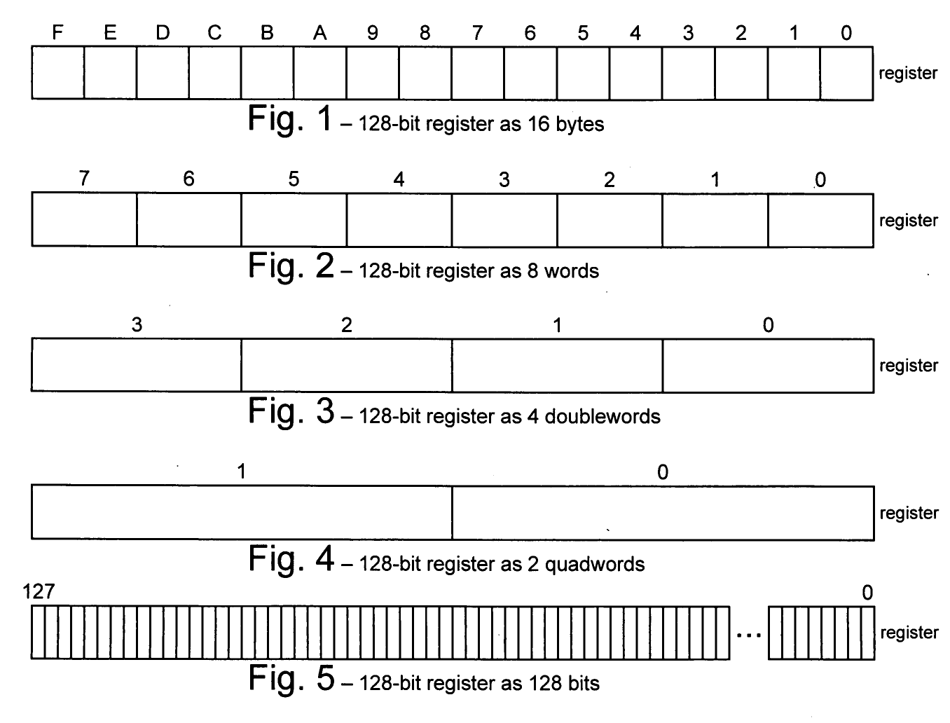

### DETAILED DESCRIPTION

The invention will be understood more fully from the detailed description given below and from the accompanying drawings of embodiments of the invention which, however, should not be taken to limit the invention to the specific embodiments described, but are for explanation and understanding only.

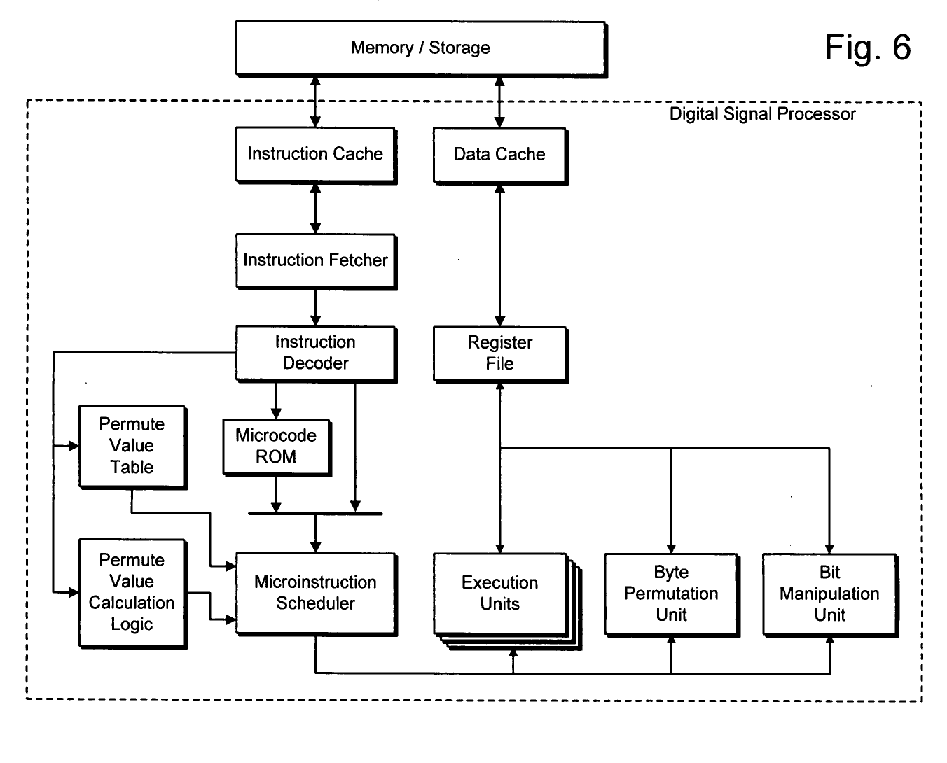

FIG. 6 illustrates a digital signal processor, microprocessor, or other form of programmable processor adapted for executing instructions. The processor includes an instruction cache and a data cache which are (typically via bus units, not shown) interfaced to an external memory/storage system. An instruction fetcher fetches instructions from the memory via the instruction cache. An instruction decoder decodes the fetched instructions into microinstructions (μops). Some instructions' μops are provided directly by the instruction decoder, and some—typically the lengthier, more complicated μop flows—are retrieved from a microcode ROM. A microinstruction scheduler receives the μops and provides them, and their operand data, to one or more execution units when the appropriate execution units and operand data are available. The execution units write result data to destinations, typically in a register file.

A processor according to the present invention may, in one embodiment, include a dedicated byte permutation unit as one of the execution units. It may also include a dedicated bit manipulation unit. Alternatively, the byte permute functionality and/or bit manipulation functionality can be implemented within one or more of the other execution units.

The present invention is centered on two capabilities: the ability to perform byte-wise permute operations, and the ability to perform bit-wise data manipulation operations, and the processor's ability to use one or both of them in implementing a variety of instructions.

The processor may additionally include a permute value table which provides predefined control values for some byte-wise permute operations, and/or permute value calculation logic which generates e.g. operand-dependent control values for other byte-wise permute operations.

The reader should make continued reference to FIG. 6 while studying the rest of this disclosure.

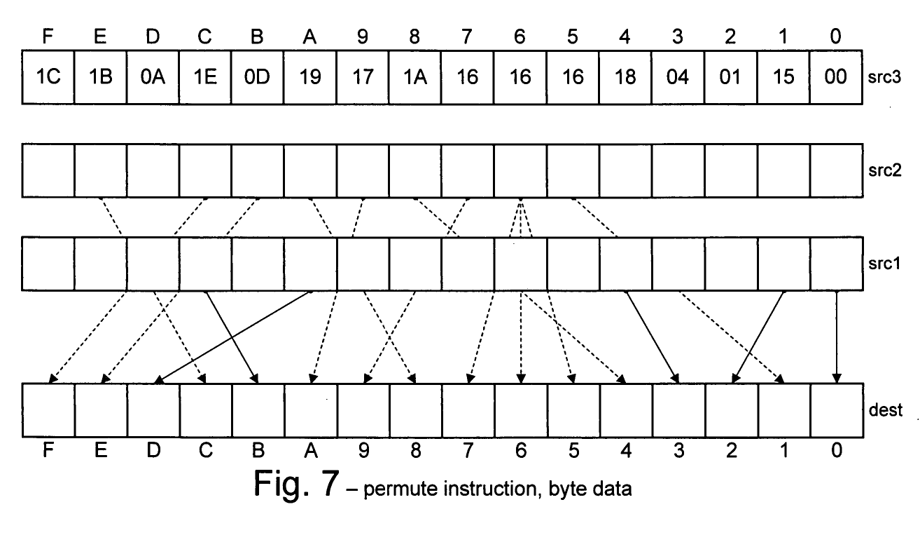

FIG. 7 illustrates the operation of a byte-wise permute instruction. The permute instruction has three input source operands src1, src2, and src3 and an output destination operand dest. Each byte src3[i] of the third source src3 specifies a location from which the corresponding byte dest[i] of the destination will be copied. The upper nibble of src3[i] is either a 0 or a 1, specifying src1 and src2, respectively. The lower nibble of src3[i] specifies which byte of that register will be copied into dest[i]. (The reader should note that the conventional terminology is somewhat unfortunate, in that a high src3[i] nibble of “1” specifies src2 rather than src1; this is because the source operands are conventionally numbered from src1 rather than from src0.)

In the example shown, src3[0] contains the hexadecimal value 00, causing src1[0] to be copied to dest[0]; src3[1] contains the hexadecimal value 15, causing src2[1] to be copied to dest[1]; and so forth. In this disclosure, dashed lines will be used to show data flow from src2 to dest, and solid lines will be used to show data flow from src1 to dest, to help the reader correctly trace the arrows in the drawings. The dashed lines from src2 to dest traverse behind src1 in the drawings.

Other processors, such as the Altivec processor from IBM, Motorola, and Apple, have had such a byte-wise permute instruction in their instruction set architecture (ISA). Applicant is not the originator of this instruction nor its functionality. Applicant believes he is, however, the first to recognize that it may be used, alone or in combination with bit-wise operations, to implement a wide variety of other data manipulation instructions on a variety of data element sizes.

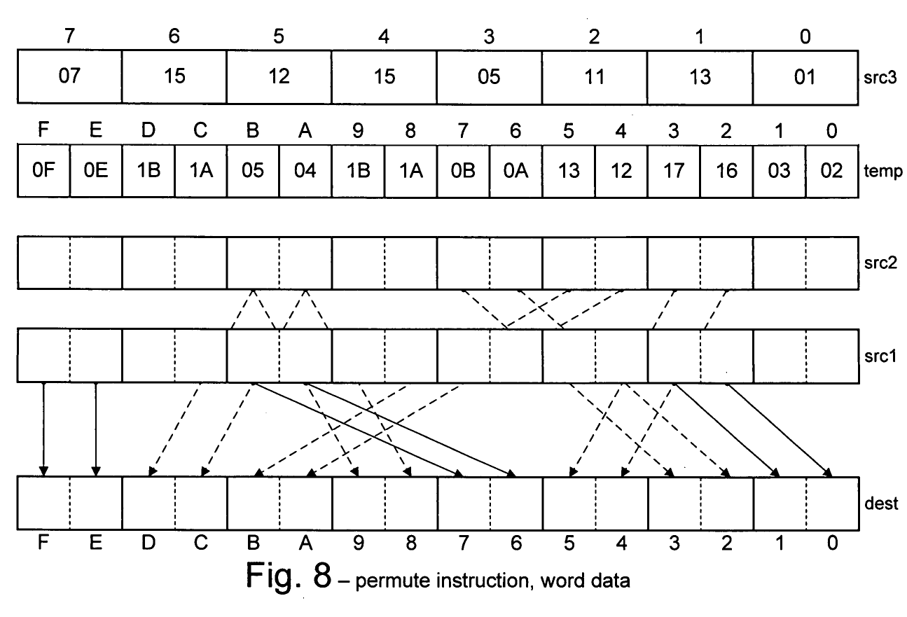

FIG. 8 illustrates the use of the byte-wise permute facility for implementing a word-wise permute instruction—perhaps the simplest expansion of the power of the byte-wise permute. The word-wise permute instruction specifies first and second source operands src1 and src2 from which word data elements are to be selected for copying into the destination dest. The instruction also has a control source operand src3 in which word sized data elements specify respective words of src1 and src2. Typically, but not necessarily, the high-order bytes of each of the control word operands in src3 will simply contain the hex value 00.

In the example shown, src3[0] contains the hexadecimal value 01, specifying that dest[word 0] should be loaded with src1[word 1], or, in other words, that dest[1:0] should be loaded with src1[3:2]. In one implementation, the processor generates a temporary control word temp from src3. The value 01 in scr3[word 0] specifies src1[word 1], so the processor loads temp[1] with the hex value 03 and temp[0] with the hex value 02. The remaining bytes of temp are loaded appropriately. In one embodiment, the instruction decoder determines that the instruction's opcode specifies a word-wise permute, and the permute value calculation logic generates the values in temp according to the values in src3.

The permute value generation logic which generates temp from scr3 for this instruction can be represented as follows (although it would typically be implemented as parallel circuitry rather than any sort of looping software).

for i:= 0; i<15; i+=2
{ temp[i] := ((src3[i]&0F)<<1) || (src3[i]&10);
temp[i+1] := temp[i]+1; }

With temp appropriately loaded with byte-wise permute values, the processor can simply execute the byte-wise permute instruction's operation, using temp instead of scr3 as its control source.

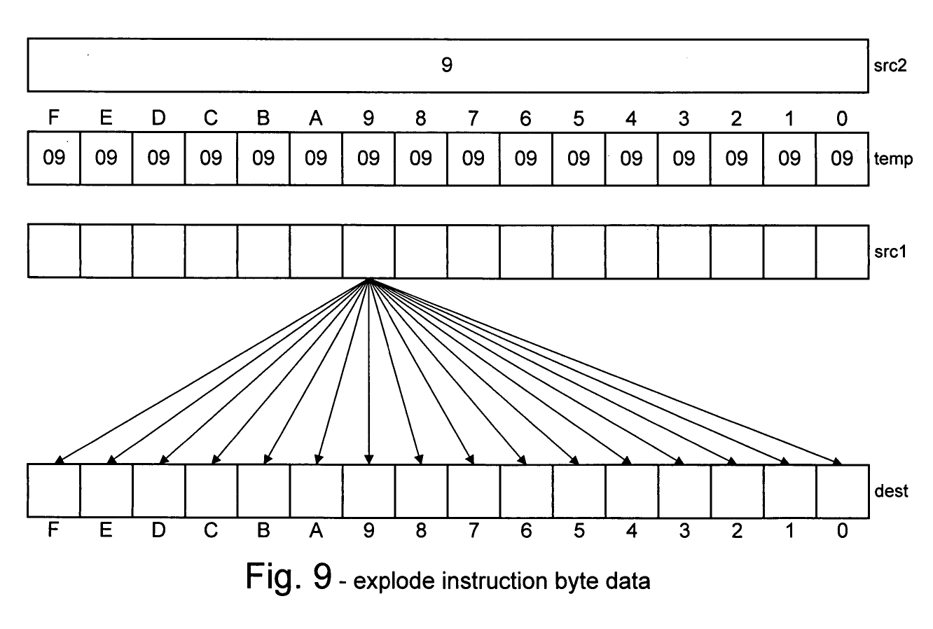

FIG. 9 illustrates the use of the byte-wise permute facility for implementing a byte-wise explode instruction. The instruction specifies a source operand src1, and provides a control operand src2 containing a single value which indicates which single byte of src1 should be copied into all byte positions of dest.

The processor implements this functionality using the permute facility. The value from src2 (typically in src2[0]) is copied into each element temp[i]. In one implementation, the facility relies on the programmer to have loaded a valid (less than hexadecimal 10) value into src2. In another implementation, the processor forces each temp[i] value to be valid by performing

for i:= 0; i<15; i++
temp[i] := src2[0]&0F

The processor then executes the byte-wise permute operation, and the specified byte of src1 is copied into each byte of dest.

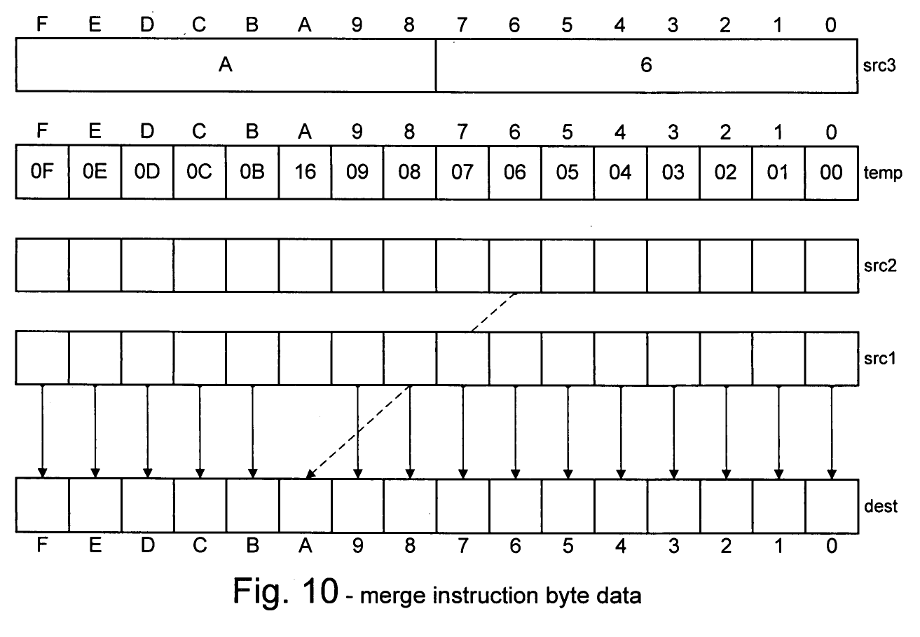

FIG. 10 illustrates the use of the byte-wise permute facility for implementing a byte merge instruction. The instruction specifies two source operands src1 and src2. A third operand scr3 contains two control values. In one embodiment, as shown, the control values are located in the low-order bytes of the two quadwords of src3. In another embodiment, they may be in any other predetermined locations, such as scr3[0] and scr3[1]. The function of the merge instruction is to copy all of src1 into dest, except that a single byte from a specified location in src2 is copied into a single byte of dest at a possibly different specified location. In one embodiment, the low-order quadword of scr3 specifies the byte src3[i] to be copied, and the high-order quadword of scr3 specifies the location dest[j] into which it is to be written.

The processor implements this functionality using the permute facility. The bytes of a temporary control register, temp[0] through temp[F] are loaded with the values 00 through 0F, except the byte temp[0X] is loaded with the value 1Y, where X is the low-order nibble from the high-order quadword of scr3 and Y is the low-order nibble of the low-order quadword of src3.

The processor then simply executes the permute operation, using temp instead of scr3 as the control register.

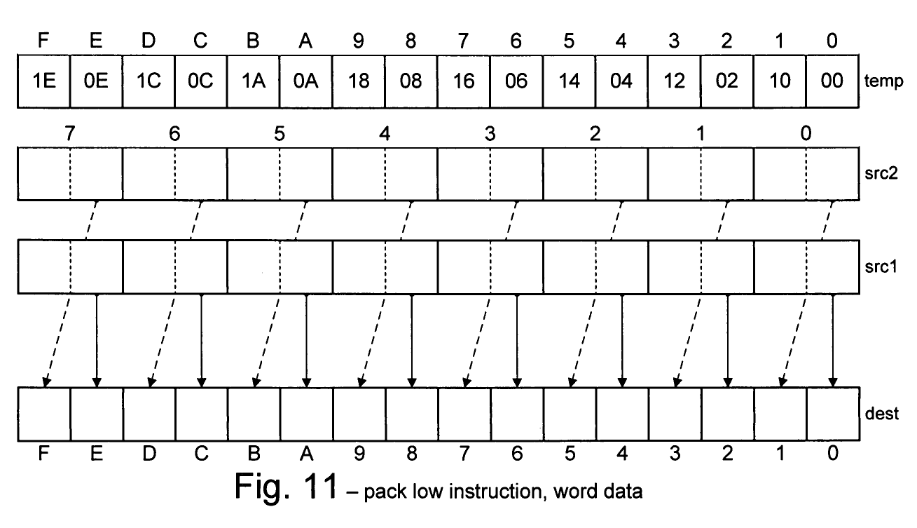

FIG. 11 illustrates the use of the byte-wise permute facility for implementing a word-wise pack low instruction. The instruction specifies two source operands src1 and src2, and a destination dest. This operation copies the low-order bytes out of the words in src1 into the even-numbered byte positions in src3, and copies the low-order bytes out of the words in src2 into the odd-numbered byte positions in src3, interlacing them as shown.

The processor implements this functionality by loading a temporary control register temp with the values shown. The values have the following pattern. Each pair, from the low-order pair to the high-order pair, gets a next even value in its bytes' low-order nibbles. Each even-numbered byte gets a 0 in its high-order nibble, and each odd-numbered byte gets a 1 in its high-order nibble. When the processor then executes the byte-wise permute operation using temp as the control source, this picks the low-order (even-numbered) bytes alternately from src1, src2, src1, src2, and so on.

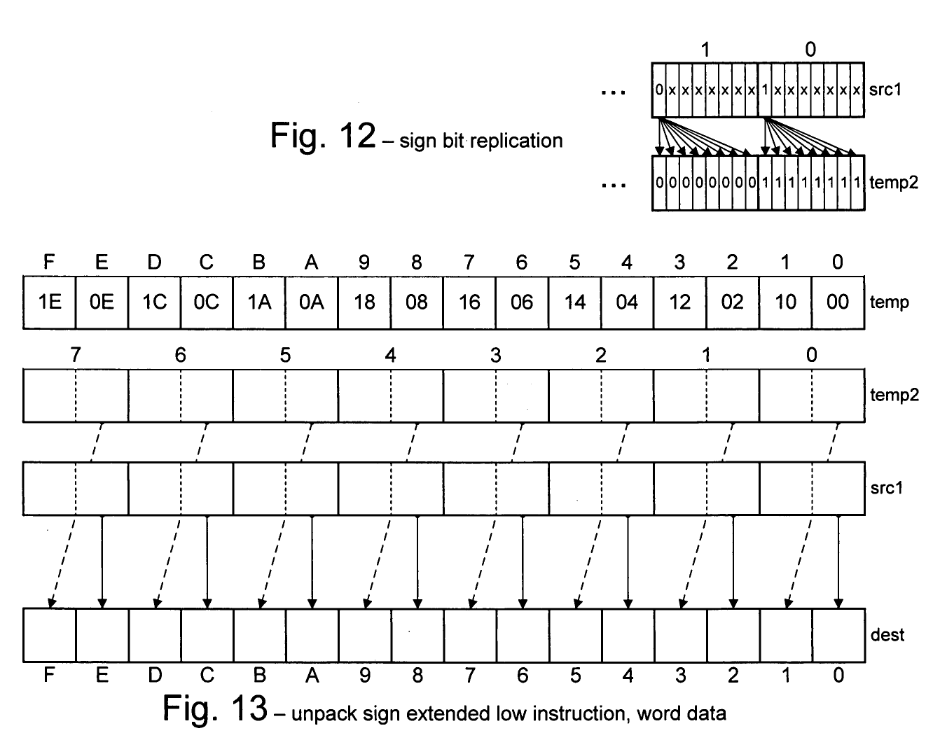

FIG. 12 illustrates sign bit replication which occurs when the processor replicates the sign bits from src1 into a temporary register temp2, preparatory to performing certain operations. The sign bit is the high-order bit of a signed byte.

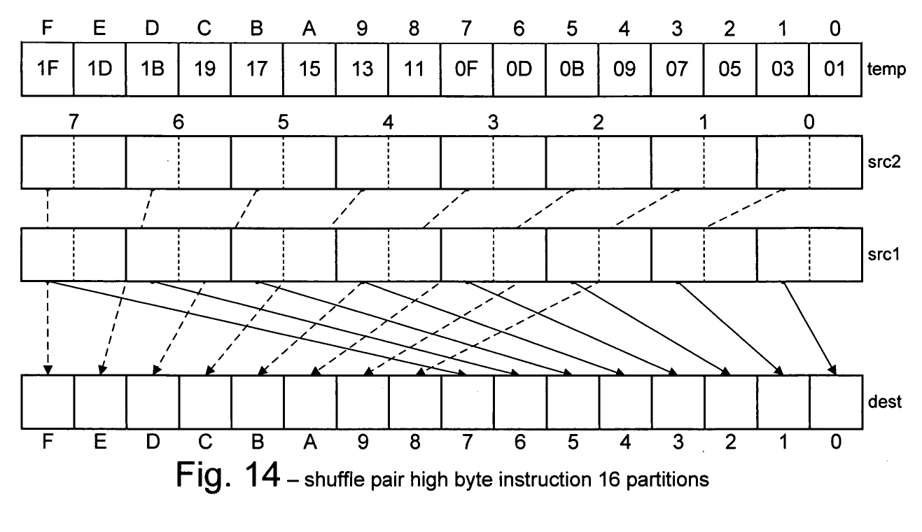

FIG. 13 illustrates the use of the sign-bit replication facility and the byte-wise permute facility in implementing a word-wise unpack sign extended low byte instruction. The instruction specifies a source operand src1 and a destination dest.

Upon encountering this instruction, the processor performs sign bit replication (not shown by arrows) of the sign bits of src1 into temp2, as explained re FIG. 12. It also loads temp with the values shown (which happen to be the same values explained in FIG. 11). It then executes the byte-wise permute operation using src1 and temp2 as the two source operands and temp as the control operand. The end result is that the even-numbered bytes of dest contain the even-numbered bytes of src1, and the odd-numbered bytes of dest contain replicated copies of their associated even-numbered bytes. (Each odd-numbered byte is associated, in word-wise data, with the even-numbered byte immediately below it.)

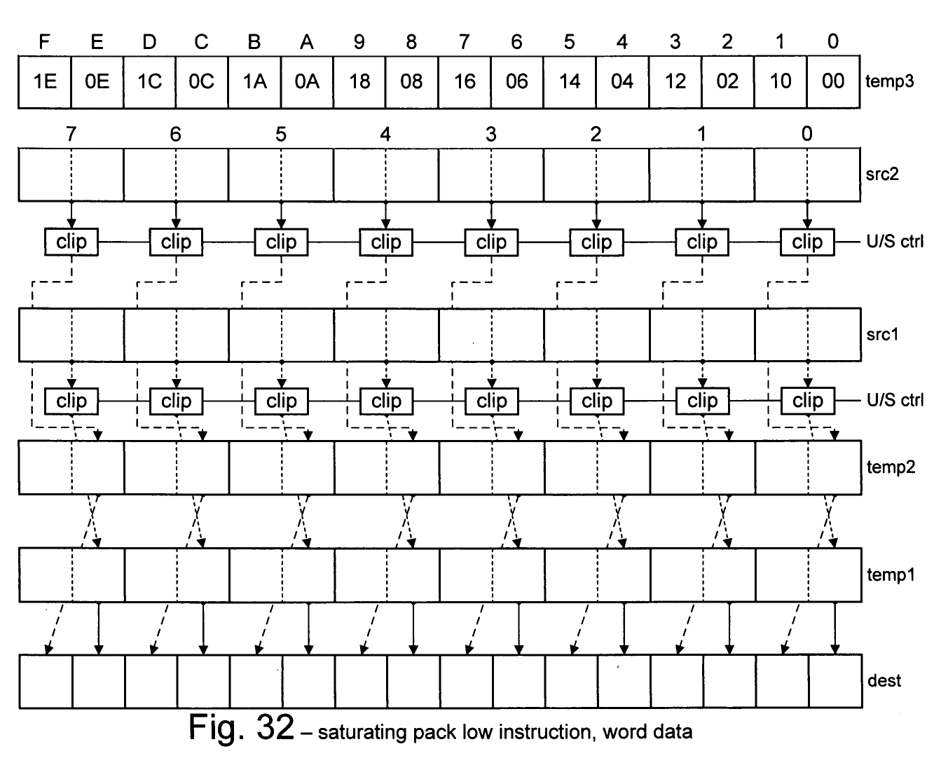

FIG. 32 illustrates one way in which a saturating pack instruction can be implemented using the facilities of this invention. The particular example shown is for a saturating pack low instruction operating upon word data (from which the low bytes are to be extracted and packed). The words of the src1 and src2 operand registers may contain signed or unsigned 16-bit values. In saturating (clipping) arithmetic, when a 16-bit value is cut down to an 8-bit value, the un/signed nature of the sources and destination should be taken into account. The src2 words are fed to respective clipping units which generate the appropriate byte values, under control of signed/unsigned control signals (“U/S ctrl”). The clipped byte results are then written to the low-order bytes of respective words in a temp2 register. Similarly, the src1 words are clipped and written to the low-order bytes of respective words in a temp1 register.

The processor loads the indicated values into the temp3 register, then uses it as the permute control for extracting bytes from the temp2 and temp 1 registers and writing the extracted bytes to the dest register.

In the embodiment shown, the instruction performs an “interleaved pack”—the low-order bytes from the two respective sources' words are written to the destination in alternating order, e.g. even-numbered destination bytes come from src1, and odd-numbered destination bytes come from src2. In another embodiment, the instruction performs a “concatenated pack” in which e.g. destination bytes 0 through 7 come from src1, and destination bytes 8 through F come from src2. The difference is simply that in the latter case, the processor will put different permute control values into temp3.

FIG. 14 illustrates the use of the byte-wise permute facility to perform a shuffle pair high byte instruction, with the source operand data in src1 and src2 partitioned into sixteen units; in other words, divided into words. The function of this instruction is to extract the high-order bytes of each word in src1 and copy them sequentially into the low-order half of dest, and to extract the high-order bytes of each word in src2 and copy them sequentially into the high-order half of dest.

The processor implements this functionality by loading the temp control register with the values shown. The pattern of the values is that they count upward from 01 by twos. After the temp register is loaded, the processor can them simply execute the byte-wise permute instruction using temp as the control register.

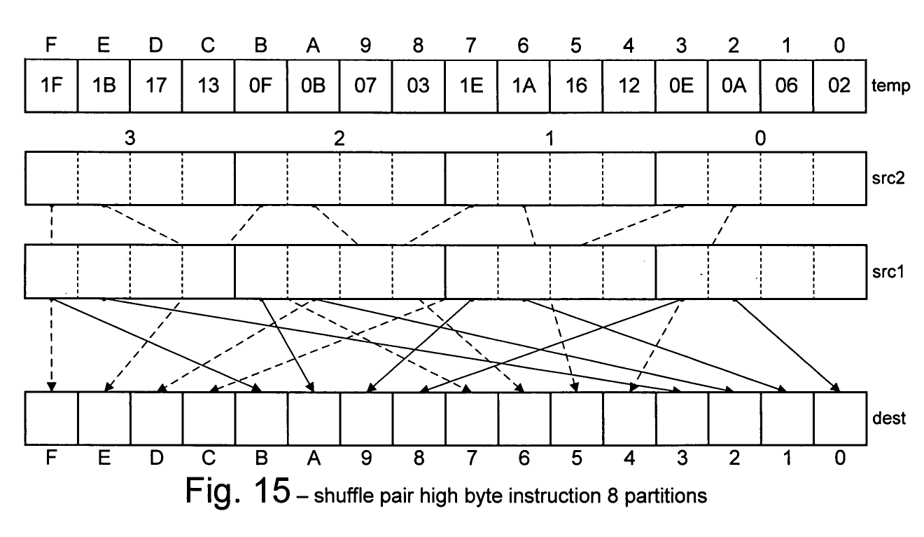

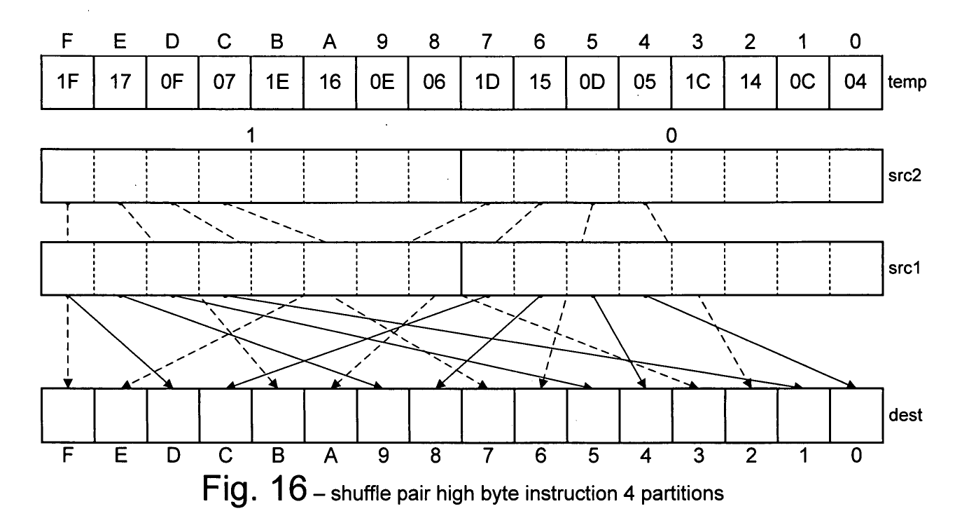

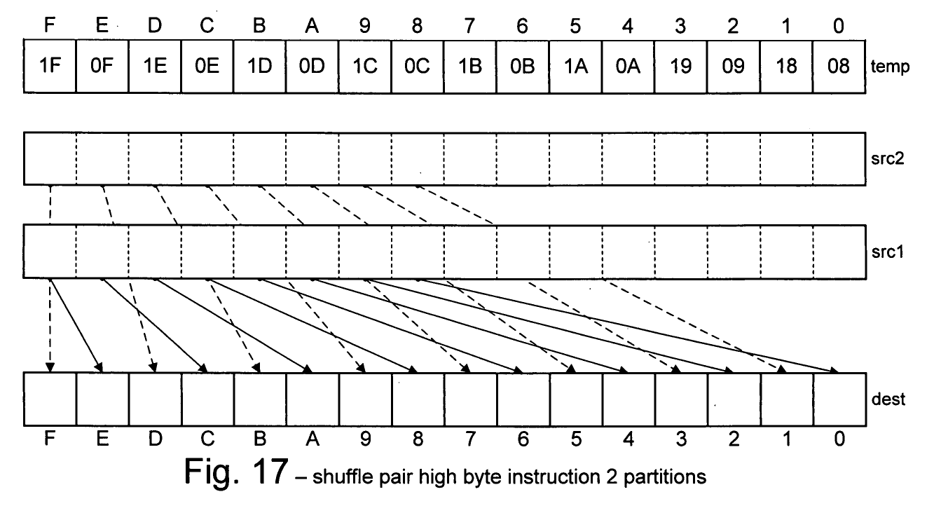

FIG. 15 illustrates the use of the byte-wise permute operation to perform a shuffle pair high byte instruction with the source operand data in src1 and src2 partitioned into eight units; in other words, divided into doublewords. The instruction extracts the high-order two bytes from the doubleword units. The lower of the bytes are copied sequentially into the low-order half of dest, and the higher of the bytes are copied sequentially into the high-order half of dest.

The processor loads the temp control register as shown, then executes the byte-wise permute instruction.

FIG. 16 illustrates the use of the byte-wise permute operation to perform a shuffle pair high byte instruction with the source operand data in src1 and src2 partitioned into four units, or quadwords. The processor loads the temp control register as shown, and executes the byte-wise permute instruction.

FIG. 17 illustrates the use of the byte-wise permute operation to perform a shuffle pair high byte instruction with the source data partitioned into only two units, each occupying one of the source operands src1 or src2. The processor loads the temp control register accordingly, and executes the permute instruction.

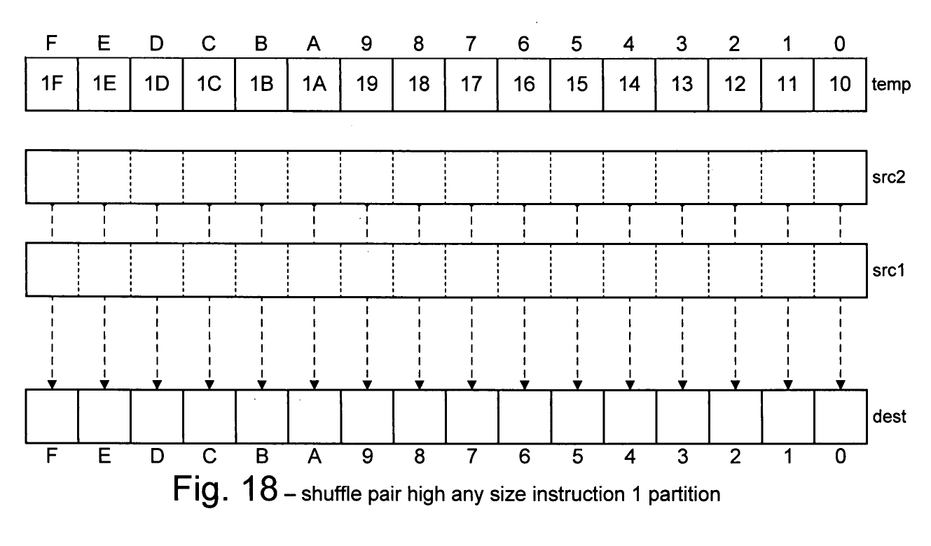

FIG. 18 illustrates the extreme case where the shuffle pair high byte instruction source is not partitioned (or is divided into one single partition). The processor loads the temp control register to cause src2 to be copied straight through to dest, then executes the byte-wise permute instruction.

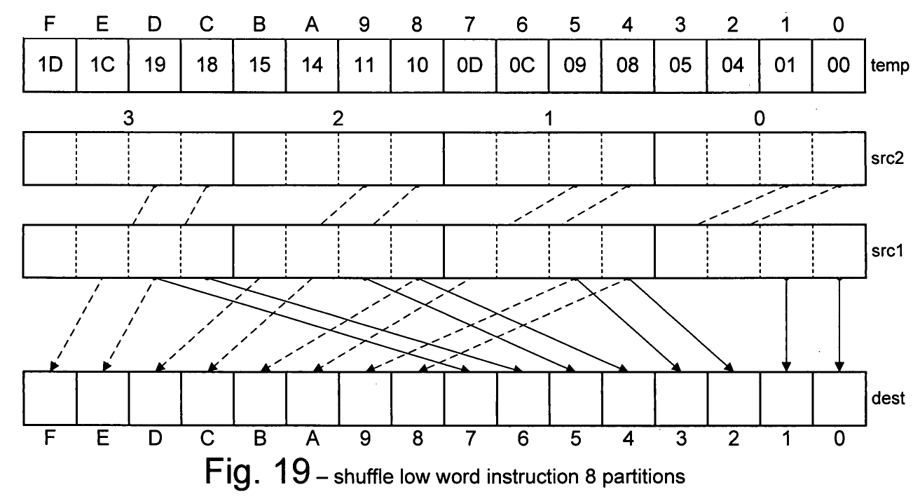

FIG. 19 illustrates the operation of a shuffle pair low word instruction with the source data partitioned into eight units. The previously describe shuffle pair high byte instruction copied individual bytes from the various partitions, hence the “byte” designation. And it copied them from the high-order half of each partition, hence the “high” designation. It shuffled them into the destination a byte at a time. The shuffle pair low word instruction, by way of contrast, copies words (adjacent, paired bytes) from the low-order half of each partition, and shuffles them into the destination a word at a time.

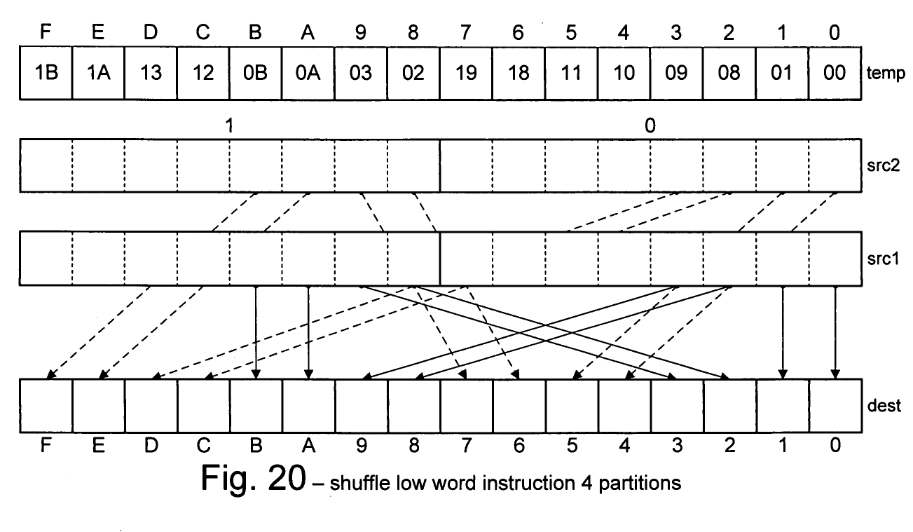

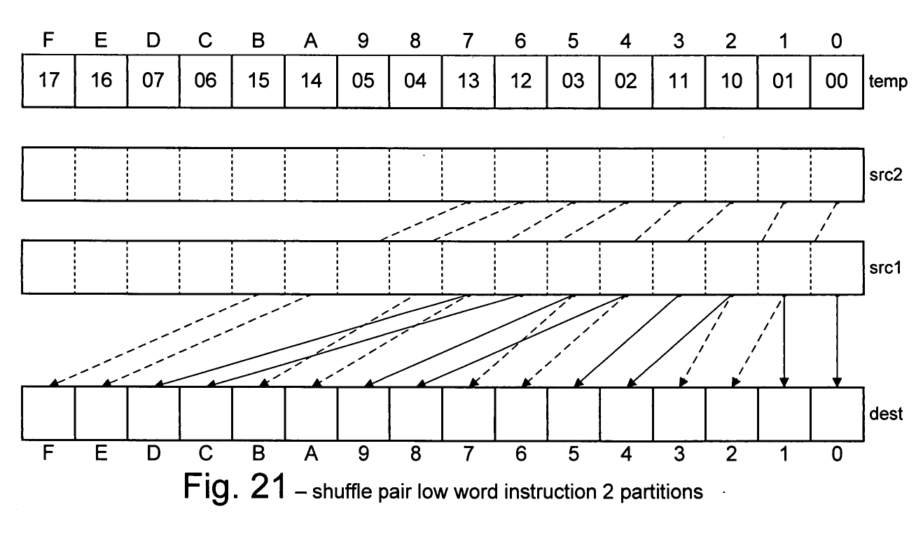

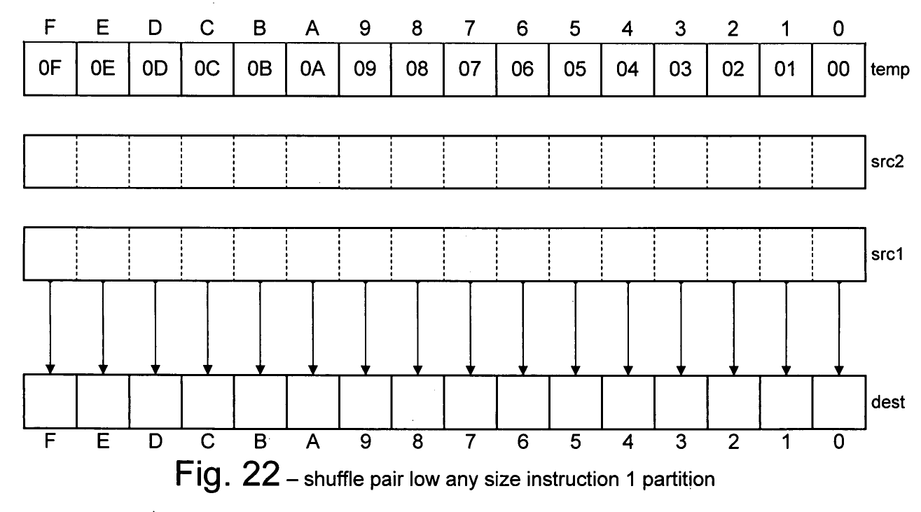

FIGS. 20-22 illustrate the shuffle pair low word instruction operating on data partitioned into four, two, and one partition. It should be noted that the single partition instructions illustrated in FIGS. 18 and 22 are representative of all single-partition shuffles, regardless of element size.

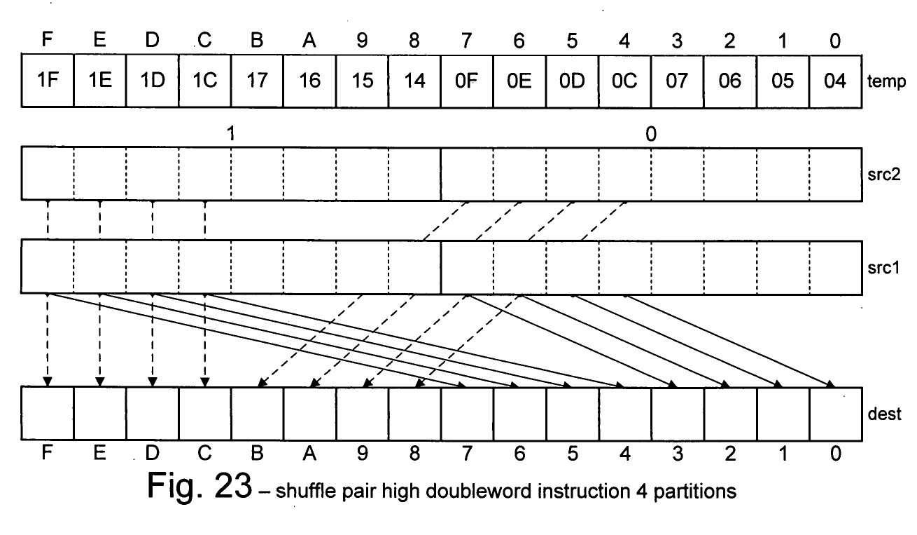

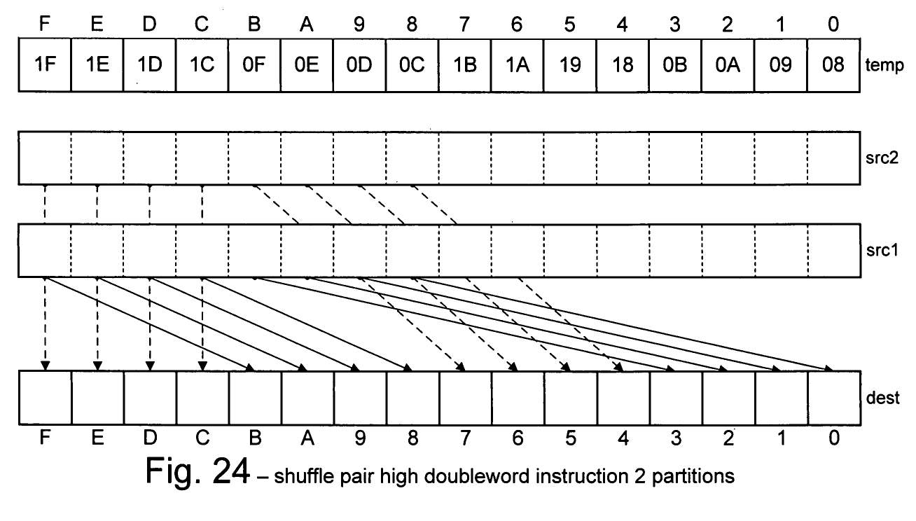

FIGS. 23-24 illustrate a shuffle pair low doubleword instruction with two and four partitions, respectively.

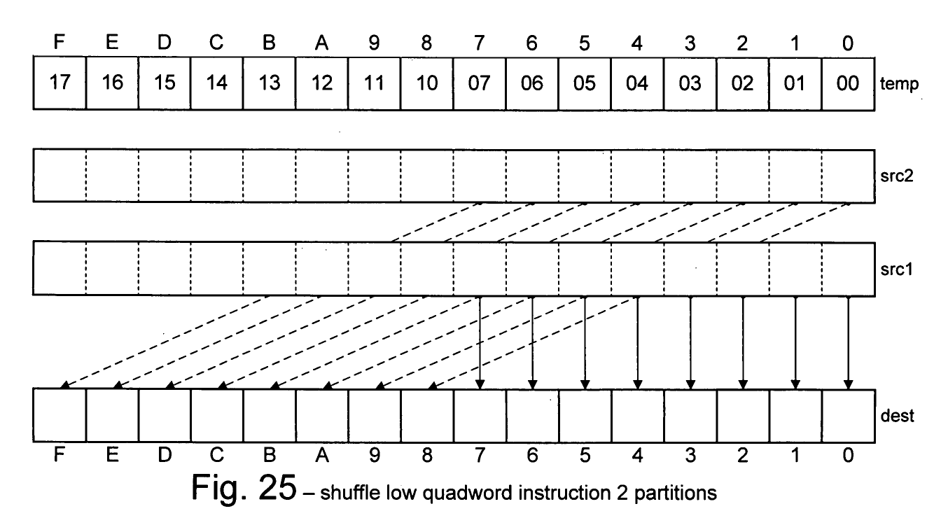

FIG. 25 illustrates a shuffle pair low quadword instruction with two partitions, and is performed in a similar manner as outlined above.

### Bit-Wise Plus Byte-Wise Movement

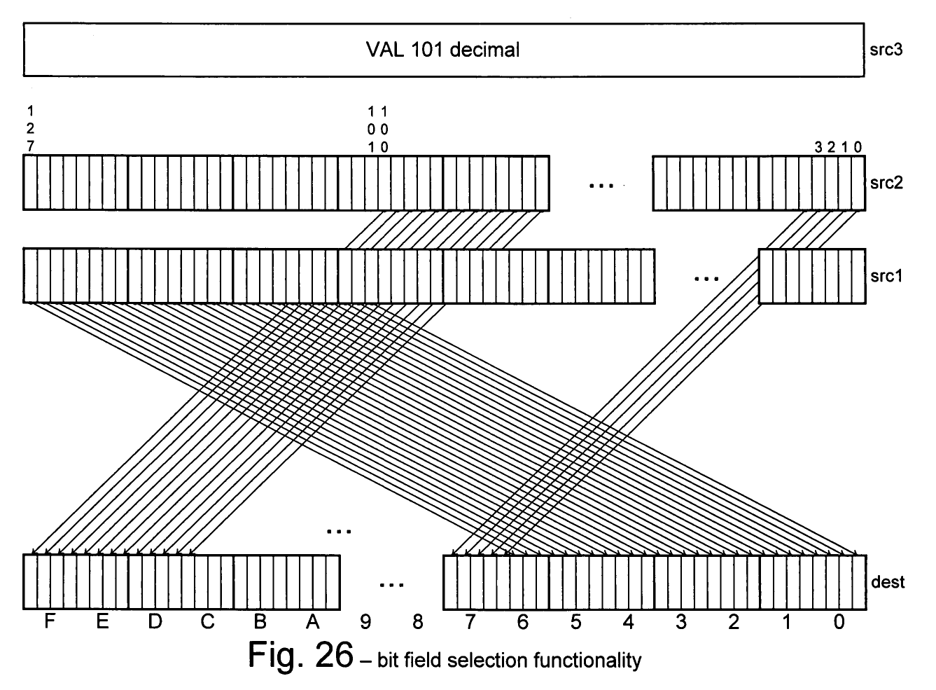

FIG. 26 illustrates the functionality of a bit-wise bit field selection instruction. Its purpose is to shift a pair of source operands left by a number of bit positions specified by a control operand src3, and write the resulting shifted value to dest. In effect, the second source src2 is treated as a high-order octoword and the first source src1 is treated as a low-order octoword, and an octoword is selected from that double-octoword from location {src2, src1 } [src3+127:src3]. The other bits of src1 and src2 are not copied to dest. If the instruction specifies the same source as both src1 and src2, the bit field selection instruction has the effect of simply performing a rotation (rather than a shift) on src1. In one embodiment, only the lower 7 bits of scr3 are used in the src3+127:scr3 calculation. In another embodiment, an immediate value is used instead of src3. (Immediate values can also be used in lieu of register operands, in a variety of other locations throughout this disclosure.)

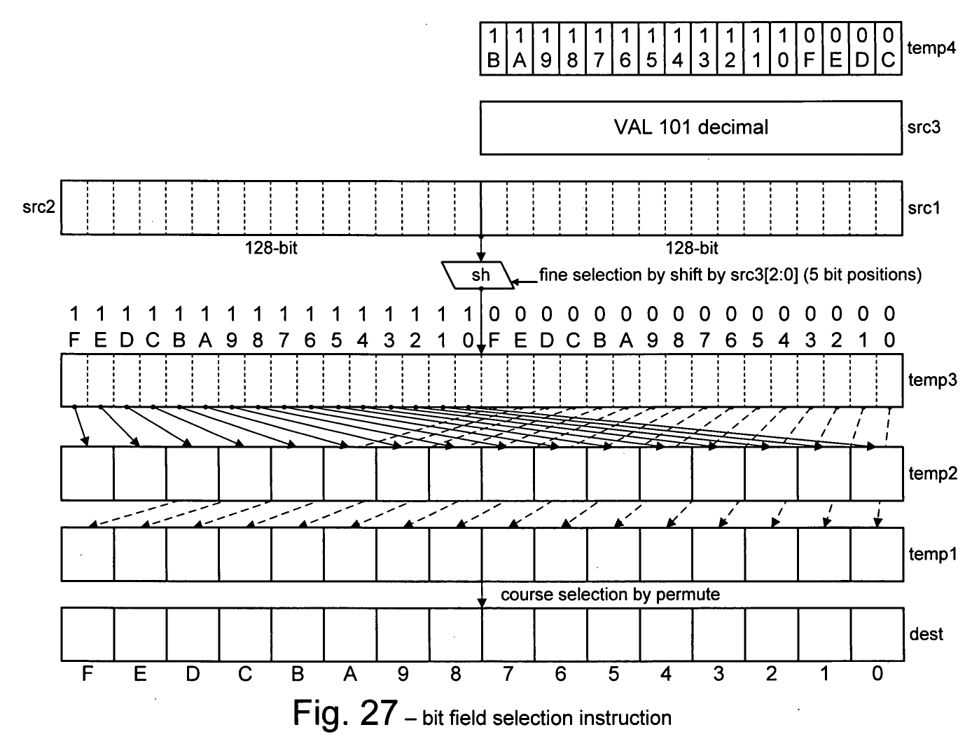

FIG. 27 illustrates one embodiment of how the bit field selection instruction can be implemented using a combination of bit-wise data movement with subsequent byte-wise data movement. The scr3 source operand specifies the bit position (shown as a decimal value) from which the processor should extract, using the specified bit position as the least significant bit, a 128-bit value from the 256-bit value which includes src1 as its low-order 128 bits and src2 as its high-order 128 bits.

The processor includes a 256-bit shifter (shown as “sh”) which, for ease of implementation, has been constructed such that it is not necessarily able to perform a full-width shift within the available time (e.g. clock cycle). In the implementation shown, the 256-bit shifter is capable of up to a 7-bit-position shift. The processor uses the low-order three bits src3[2:0] to control the shifter. In the particular case shown, 101 (decimal) in scr3 equals 12*8+5, and scr3[2:0] will contain the decimal value 5 (with the remaining 96 represented in the higher-order bits of src3).

The processor writes the shifted 256-bit value to 256-bit temporary register temp3, then copies the high-order 16 bytes into temp2 and the low-order 16 bytes into temp1. Alternatively, the shifter output could be written directly into temp2 and temp1 as indicated.

The processor then writes the value src3[7:3], which happens to be 0C in the case of scr3 =101 decimal, into permute control register location temp4[0], and sequentially higher values into src3[1] through scr3[F]. More specifically, it writes the low-order 5 bits of sequentially higher values into those locations, zeroing the high-order 3 bits of the values written; this accommodates wrap-around if the scr3 value was greater than 128.

The processor then executes the byte-wise permute operation, writing the results to dest. Thus, the combination of a fine-grain (sub-byte) shift is used to get the operand data into a configuration in which a course-grain (byte-wise) permute can be used to effect a shift that is significantly greater (in terms of the shift count) than the shifter can itself perform. This enables the shifter to be significantly simplified and sped up and its area and power consumption reduced.

Rotate instructions can be similarly implemented.

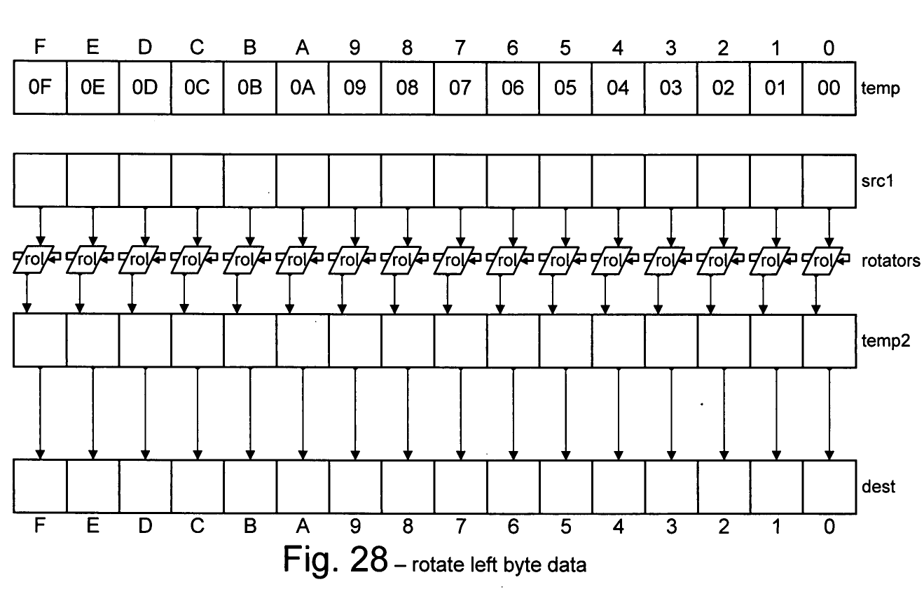

FIG. 28 illustrates how the processor may be constructed to execute a rotate left instruction with byte data granularity. The instruction specifies a source operand src1 and a destination dest. The processor includes sixteen rotators, each in the data path of a respective byte of the byte permutation execution unit.

Upon encountering the rotate left byte data instruction, the processor loads the temporary control register temp with the sequential values as shown. Each value is simply the number of its byte position within the register. The processor then executes the byte data left rotate by passing each src [i] byte to its corresponding rotator, and the result from each rotator is written to a respective, corresponding byte of a temporary destination register temp2. The processor then executes the byte-wise permute operation using temp as the control, temp2 as the source, and dest as the destination. With the sequential values in temp, no byte-wise movement is caused.

In one embodiment, the one 256-bit-wide shifter of FIG. 27 and the sixteen 8-bit-wide rotators of FIG. 28 can be constructed using the same components. This is true of other width configurations shown elsewhere in this disclosure, as well.

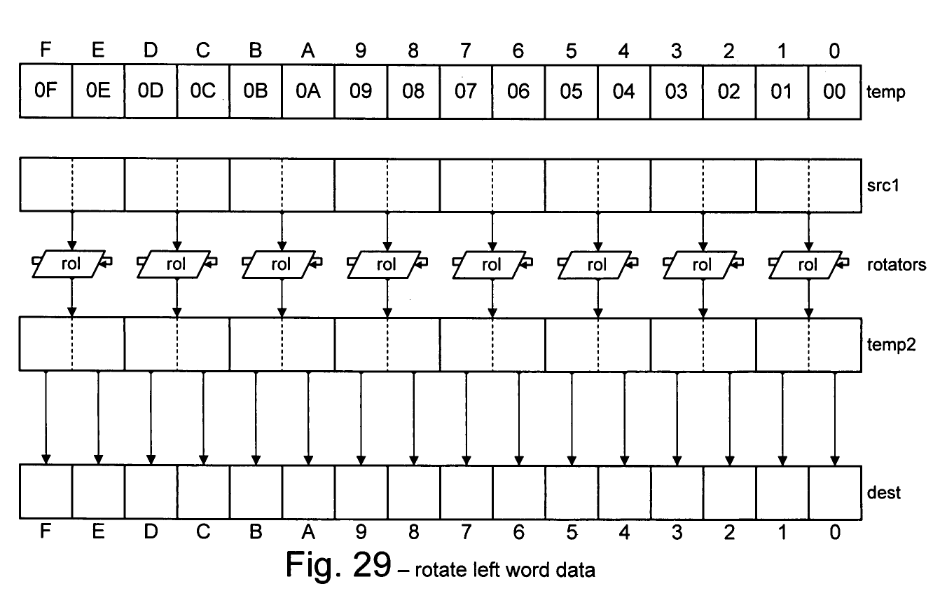

FIG. 29 illustrates a similar operation performed for a rotate left instruction specifying word data. Each two-byte position in the data path includes a 16-bit rotator. The processor uses the same sequential temp values as in FIG. 28. After the 16-bit rotated values have been written to temp2, the byte-wise permute operation copies them to dest.

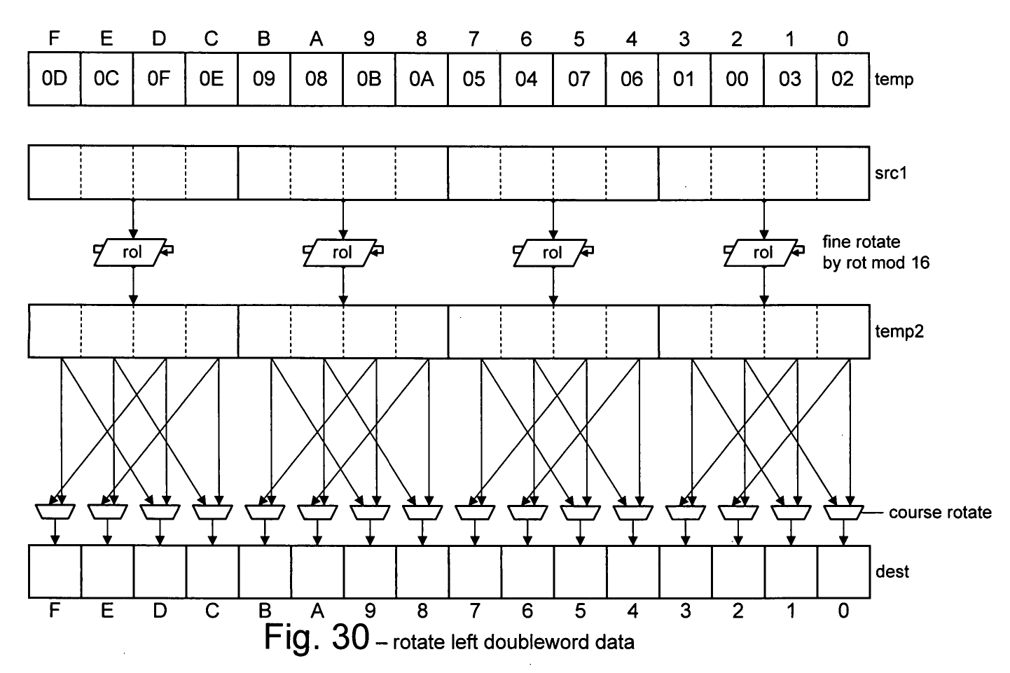

FIG. 30 again introduces the concept that having the byte-wise permute capability can be used to simplify the processor's bit-wise data movement facilities, without losing any overall data movement capability.

Assume that the instruction set architecture (ISA) of the processor mandates that the processor be able to execute up to 32-bit rotates on doubleword (32-bit) data elements. In one implementation, not using this invention, the processor could be provided with four 32-bit rotators each capable of rotating any number of bit positions between 0 and 32. Such a rotator is somewhat complex and its design may limit the maximum clock speed of the processor.

More advantageously, the processor can be constructed to utilize the present invention's byte-wise permute operation in combination with a less capable, simplified rotator. For example, as illustrated, each rotator may be capable of no more than 16-bit rotation.

The processor loads the temporary control register temp with the values shown, and provides each doubleword value from src1 to its respective rotator. The rotator is 32 bits wide, but is capable of only 16 bit positions' rotation at a time. The processor takes the rotate count supplied by the instruction, and provides it modulo 16 (by sending only the low-order four bits) to each of the rotators. The outputs of the rotators are written to respective doublewords in temp2. This is a “fine grain rotate” operation.

The processor then performs a “course grain rotate” operation to complete the rotate instruction. In one implementation, the processor may include a set of multiplexers each wired to receive values from two byte positions in temp2, as shown; one is a straight pass-through, and one is two bytes removed within the doubleword. The processor can then use the fifth bit position of the rotate count specified by the instruction, to control which of these two values is muxed through to the corresponding byte position in dest. The fifth bit position is the “16's value”, and is 1 if the shift count is between 16 and 31.

Alternatively, the processor can use this fifth bit position in determining whether to load temp with the values shown, or with sequential “00 01 02 . . . 0F” (from 1sb to msb, right to left) values. Then, after the fine-grain rotate, the processor can simply invoke the byte-wise permute operation. In this implementation, the course rotate multiplexers are not needed and can be omitted from the machine.

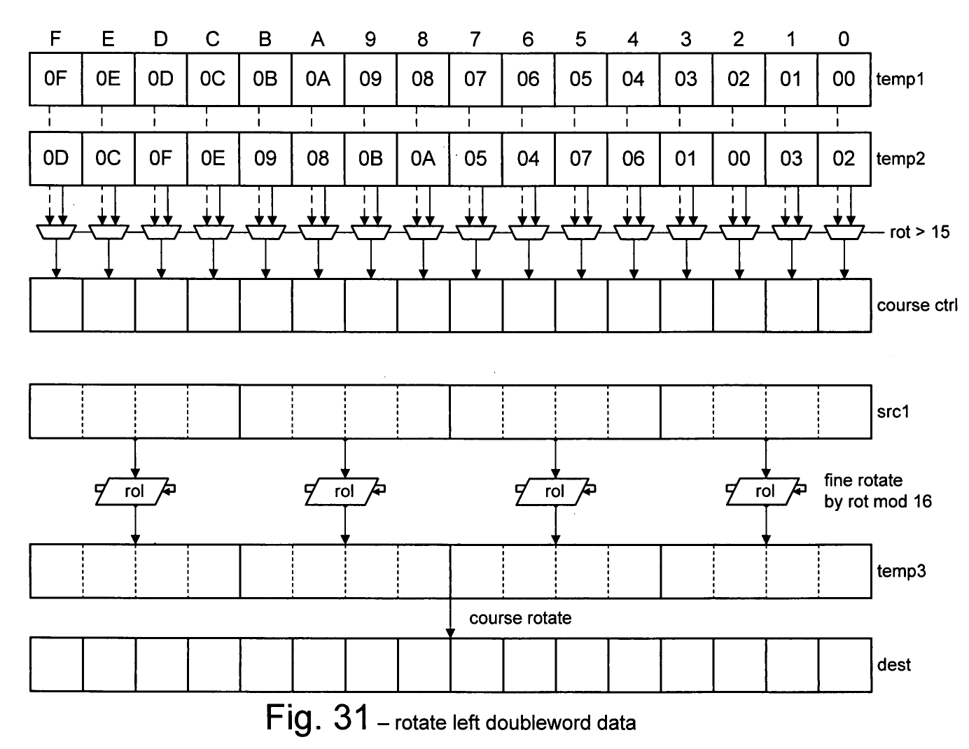

FIG. 31 illustrates the execution of a rotate left instruction upon doubleword data in that manner. Upon detecting the rotate left opcode, the processor loads a first control register temp1 with sequential pass-through values, and loads a second control register temp2 with the “rotate two byte positions” values shown. Then, depending on whether the rotate count is greater than 15, one of those two control data sets is muxed into a course rotate control register. Alternatively, the course control register could be loaded directly e.g. by microcode, rather than creating two sets and throwing one away.

The src1 data are fine grain rotated by the 32-bit rotators, using the rotate count modulo 16, and the results are written to an intermediate destination register temp3. The processor then invokes the permute operation using temp3 as the source and course ctrl as the control, and writes the results to dest.

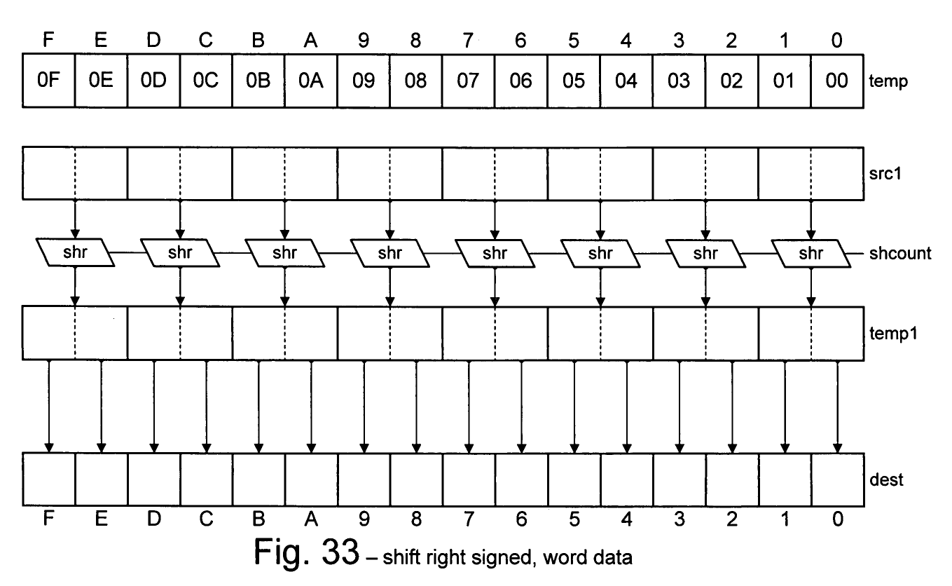

FIG. 33 illustrates one way in which a shift right signed data instruction can be implemented. In this instance, the processor has eight shifters (“shr”), each of which is capable of shifting its data up to 16 bit positions according to a 4-bit shcount shift count control input. The instruction specifies the source operand src1, the shift count, and the destination dest. The processor loads the temp register with the pass-through permute control values shown, and the processor executes the permute operation on temp1 to write the shifted results to the dest register.

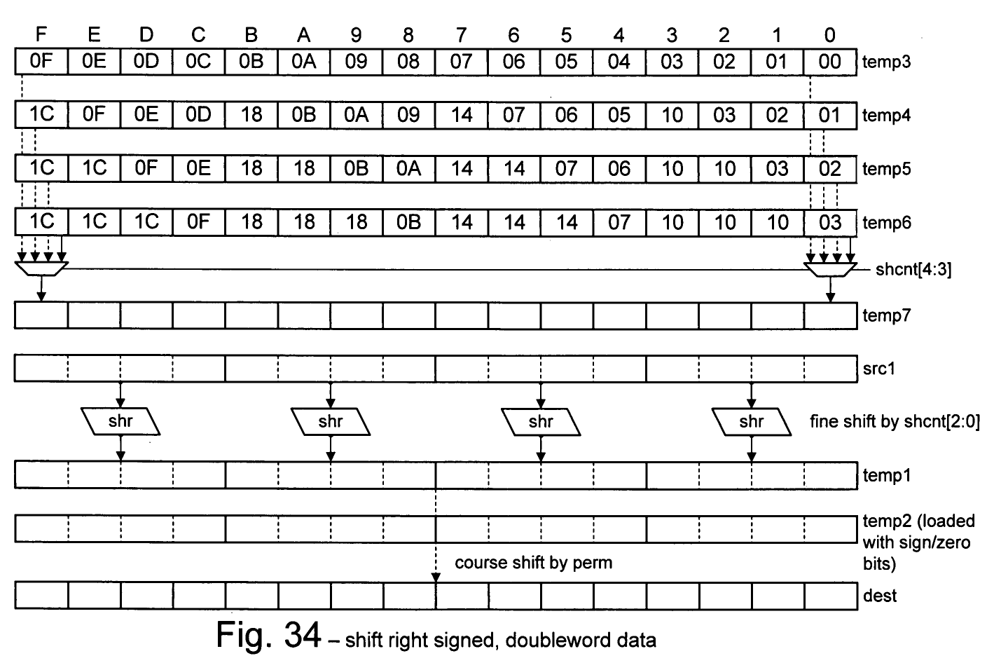

FIG. 34 illustrates the more complicated scenario where the shift instruction specifies a shift count that is greater than the shift capabilities of the shifters. In the example given, four 32-bit shifters are capable of up to a 7-bit shift each, and the instruction can specify up to a 31-bit shift. The processor loads temp3 through temp6 with permute control values which shift by zero, one, two, and three byte positions, respectively. Then, the course permute control values are selected (into a register, as shown, or for direct use e.g. on wires) from those values by muxes according to shift count bits shcount[4:3]. The operand data in src1 are “fine grain” shifted by shcnt[2:0] bit positions, and the intermediate results are written to temp7. If the instruction specifies signed data, then the sign bits of the respective doublewords are copied into the low-order bytes of the corresponding doublewords of temp2. If the instruction specifies unsigned data, then those low-order bytes are populated with zeroes. The processor then uses the course grain permute to complete the shift.

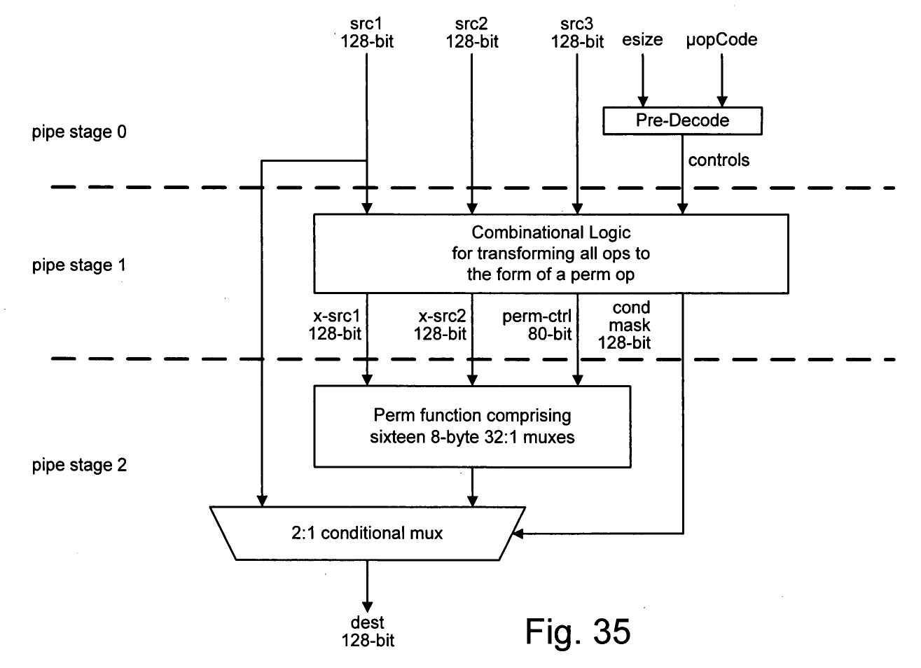

FIG. 35 illustrates one embodiment of a data path pipeline which can be used in implementing this invention. In a first pipe stage, the instruction is pre-decoded to generate a set of control values based upon the operation code (μopCode) and element size (eSize) indicated in the instruction. In a second pipe stage, those control values are used to control the operation of combinational logic which receives any src1, src2, and scr3 values from the instruction's operand fields and transforms them (e.g. by performing fine-grain data manipulation) to put them into a suitable form (e.g. byte-aligned) for a subsequent course-grain perm operation. In a third pipe stage, the perm operation is performed on the transformed src1 and src2 values (xsrc1 and xsrc2, respectively) in accordance with a set of generated permute control values. If the machine is equipped to handle conditional instructions, the second pipe stage's combinational logic also generates a conditional mask, which is used in the third pipe stage to select between the original src1 value and the output of the perm function. The result is written to the destination, and is typically also sent to a slot mux and to a bypass network for early availability as a source operand in other instructions.

### Bit Field Selection Instruction

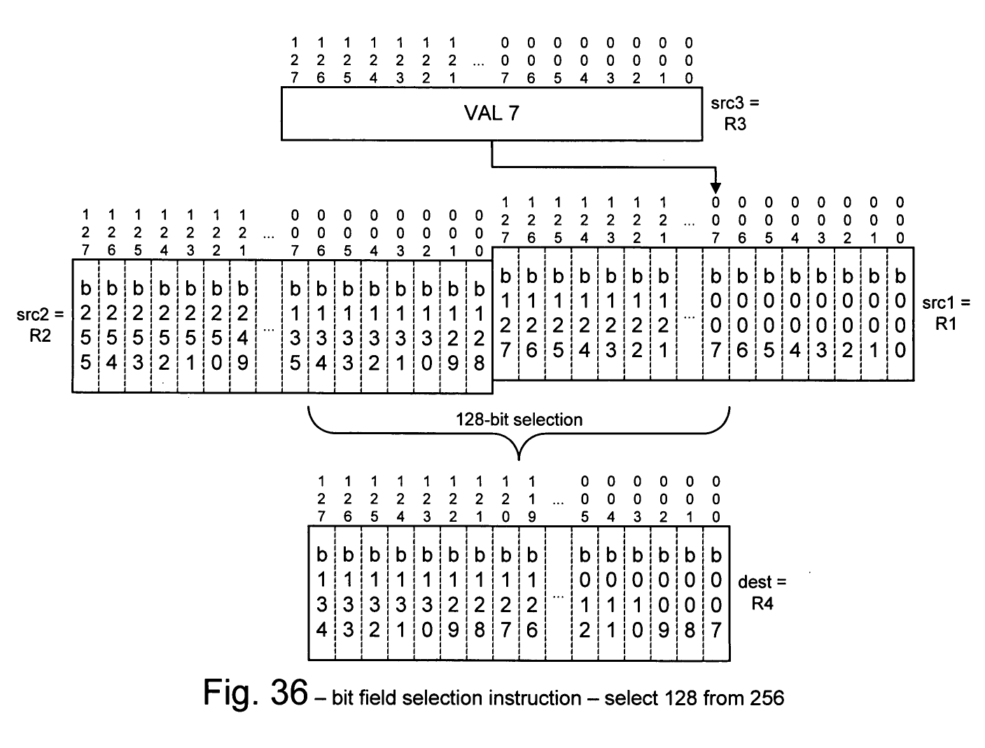

FIG. 36 illustrates the operation of the bit field selection instruction of FIGS. 26 and 27. The instruction specifies a first source operand designator src1 and a second source operand designator src2, which in the example given, point at 128-bit registers R1 and R2, respectively. The instruction also specifies a third source operand designator src3, which in the example given, points at 128-bit register R3. The instruction specifies a destination register designator dest, which in the example given, points at 128-bit register R4. In other embodiments, the third source operand is not the same size as the first and second source operands, and need not necessarily be of the same type. For example, src1 and src2 could point at 128-bit register or memory locations, while scr3 could be an 8-bit immediate data field in the instruction, or scr3 could be a 3-bit pointer into a group of 16-bit registers, and so forth.

If, at various points in this disclosure, the inventors state that e.g. “src1 contains the value 128” or simply “src1 is 128” or the like, it is really meant that “src1 points at a register or memory location which contains the value 128”. This looseness in terminology is commonplace in the industry and well understood by those of skill in the art.

The value held in scr3 indicates which bit position in the source identified by src1 is to be copied into the least significant bit (LSB) of the result. The remaining bits of the result are taken from consecutive adjacent bits in the registers identified by src1 and src2, as shown.

For convenience of illustration and clarity of explanation, when a register or a bit position in a register is indicated as containing a specified value, the value is preceded with “VAL”. For example, in the example given, register R3 is shown to hold the value 7, indicated as “VAL 7”. And when a bit position's particular value is unspecified, it is identified simply by its bit position and is preceded with “b”. For example, bits 0 through 127 of register R1 are identified as “b000” through “b127” respectively, and bits 0 through 127 of register R2 are identified as “b128” through “b255” respectively (because, in this form of the instruction, the registers identified by src1 and src2 are treated as one 256-bit conglomerate source). The vertical split between src1 and src2 is merely for visual clarity of the illustration.

Thus, in the example given, 128 bits are selected from the R2:R1 conglomerate source, with the LSB selected from bit position b007 (as specified by R3), and the result written to destination register R4 includes bits b127:b007 from R1 and bits b134:b128 from R2.

It should be noted that scr3 can be used to perform a conditional selection between src1 and src2. If scr3 is 0, src1 will be copied in its entirety to dest, but if scr3 is 128, src2 will be copied in its entirety to dest.

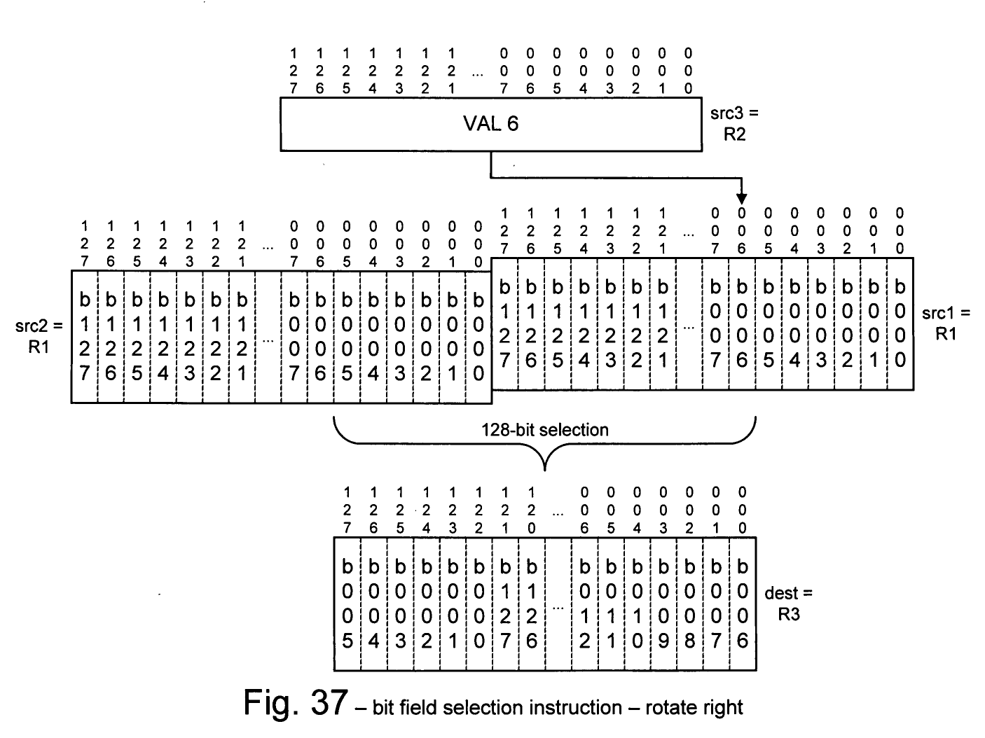

FIG. 37 illustrates the operation of the bit field selection instruction in performing a rotate right operation on a 128-bit source. The first and second source operands src1 and src2 are both pointed at the same register R1. The third source operand points at register R2, and the destination dest points at register R3. The third source specifies how many bit positions the source should be rotated to the right; in the example given, “VAL 6” specified six bit positions.

With both source operands pointed at the same register R1, any 128-bit field selection effectively performs a rotate right, because the LSB of the src2 source is adjacent the MSB of the src1 source, implicitly performing the wrap-around of the rotate operation.

In the example given, the rotate count is 6 in R2, and the destination register is written with the values shown, with b006 in the LSB and b005 in the MSB, with the wrap-around occurring 6 bits from the MSB.

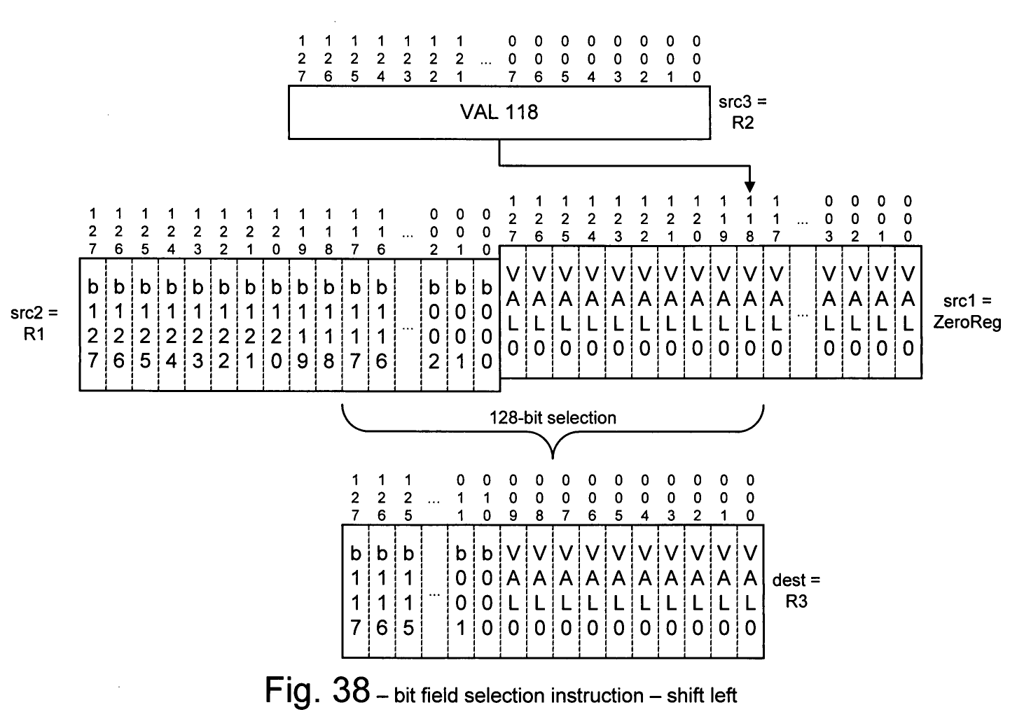

FIG. 38 illustrates the operation of the bit field selection instruction in performing a shift left operation of the arithmetic shift variety in which zeroes are shifted in. The compiler points src2 at the register containing the value to be left shifted, and src1 at a special register ZeroReg which contains 128 zeroes (“VAL 0”).

Because this is a leftward operation rather than a rightward operation, the compiler has to do a bit of setup, to get the desired result. For a left shift count N specified by the source code, the compiler loads the value 128—N into the scr3 register. In the example given, the shift count was 10, and the compiler has placed the value 118 into src3. This is because the bit field selection needs to select N bits from the MSB end of src1, rather than from the LSB end. When the instruction is then executed, 128 bits are copied from src2[(src3−1):0] and src1[127:src3].

Alternatively, if the machine does not include a special ZeroReg, the compiler can in a previous instruction load the value 0 into some register, then point src1 at that register in the bit field selection instruction that is to perform the shift left.

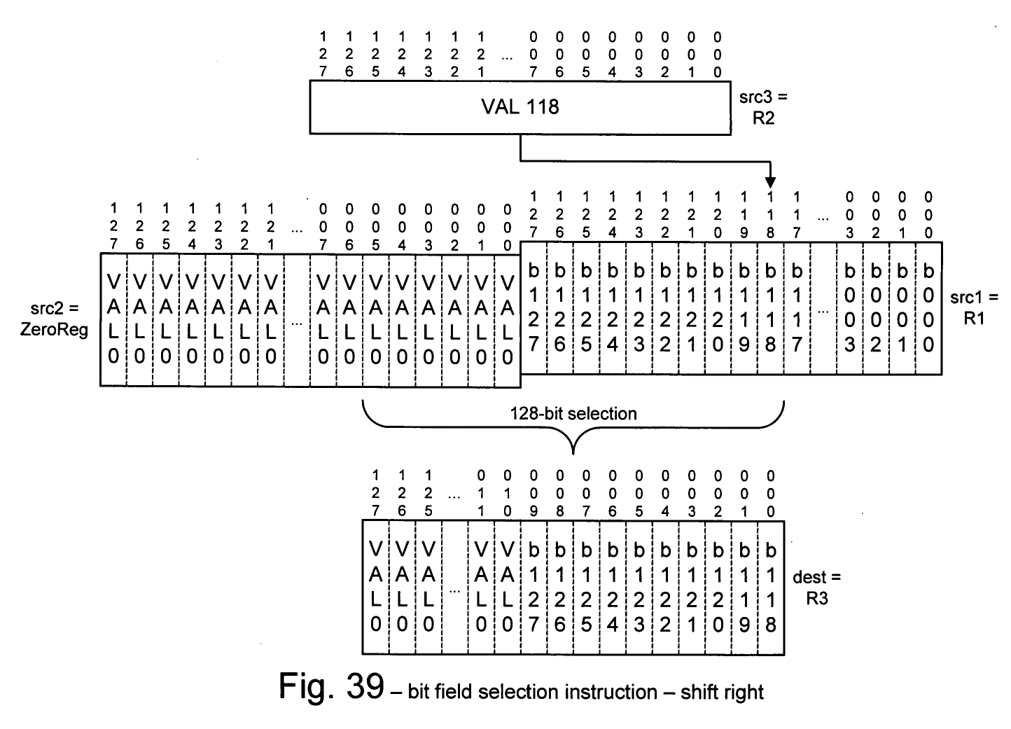

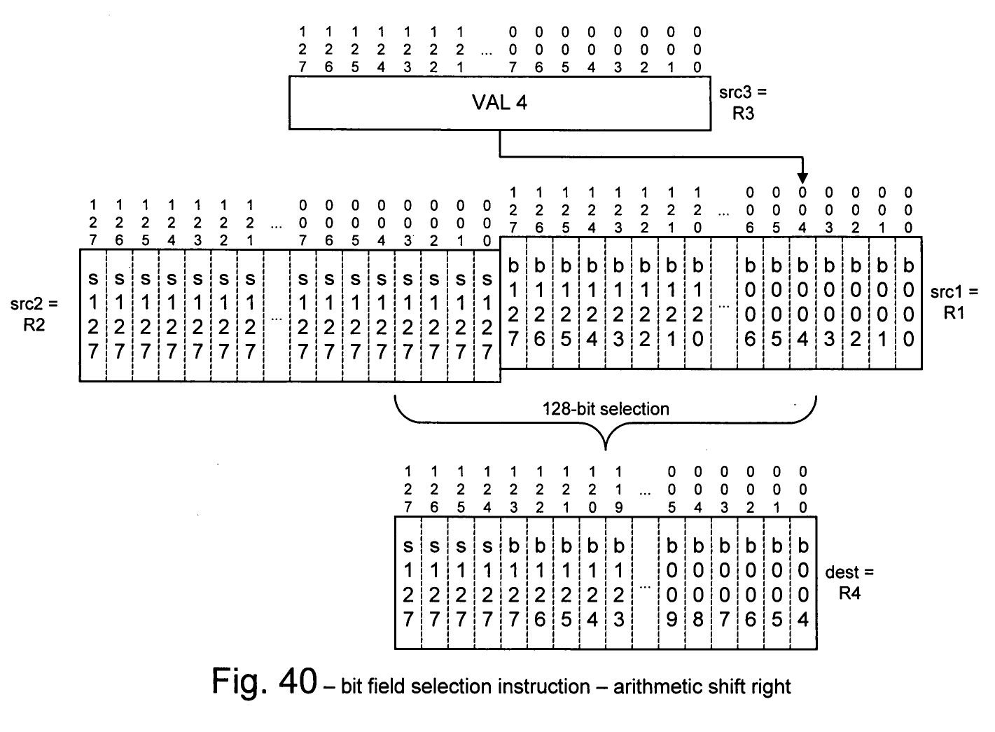

FIG. 39 illustrates the operation of the bit field selection instruction in performing a logical shift right operation, of the type in which zeroes are shifted in. The first source src1 points at the register R1 holding the value to the shifted, the second source src2 points at the ZeroReg (or a zeroed register), the third source scr3 points at the register R2 holding the shift count (in this example 118), and the destination dest points at the register R3 into which the results are to be written. In other examples, the dest can, of course, point to e.g. R1 and the source will be overwritten with the shifted value.

128 bits are selected from src2[(127−src3):0] and src1[127:src3]. The destination will then contain a value having the number of leading zeroes specified as the shift count.

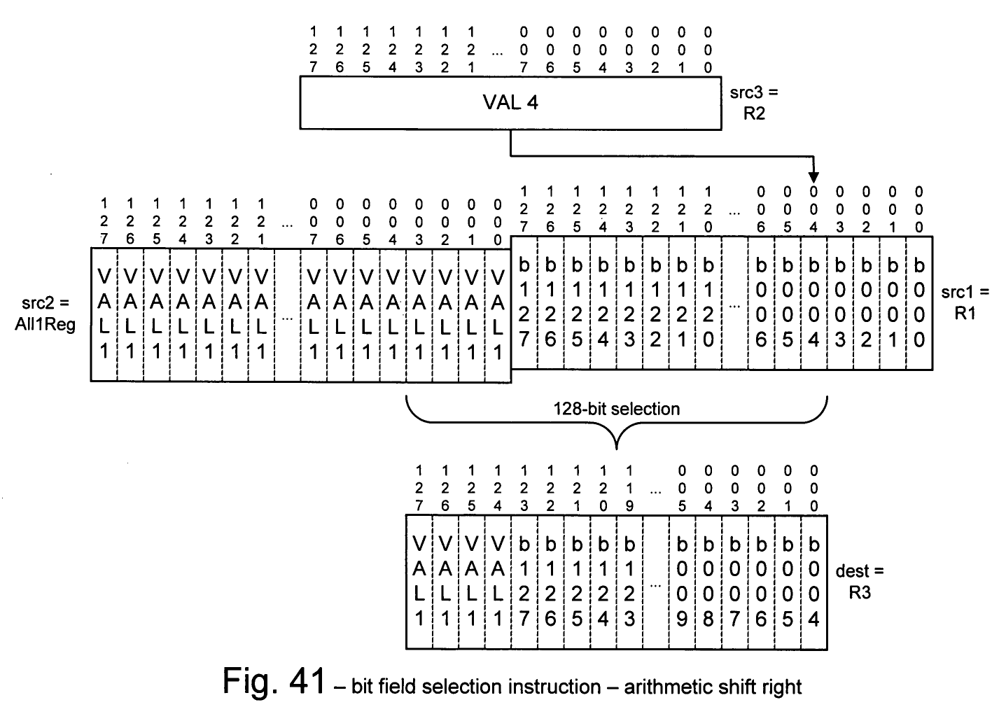

FIG. 40 illustrates the operation of the bit field selection instruction in performing an arithmetic shift right operation, of the type in which the sign bit is replicated rather than zeroes being shifted in. In a previous instruction, the sign bit b127 (of the value in the source R1 to be shifted) is copied into every bit position of a second source register R2. These copied bits are denoted as “s127”, suggesting that each is a copy of the sign bit.

The compiler sets up the bit field selection instruction such that src1 points at the source register R1, src2 points at this replicated sign bit register R2, and the shift count is loaded into a register pointed at by src3. Then, when the bit field selection instruction is executed, 128 bits are copied from R2[R3−1:0] and R1[127:128−R3]. The result written to R4 will thus be right shifted by R3 bit positions, and will contain R3+1 copies of the original sign bit (including the original sign bit itself).

FIG. 41 illustrates an alternative operation of the bit field selection instruction in performing an arithmetic shift right. In a previous instruction, the code has tested the sign bit b127 and determined it to be a one. Then, the code has, responsive to that determination, branched to a bit field selection instruction which has its src2 pointed at a special All1Reg register which contains 128 ones (“VAL 1”). The result written to R3 will contain R2 (shift count) ones from the All1Reg as well as the original sign bit 127.

If the previous instruction had, instead, determined the sign bit to be a zero, the code would then have branched to the bit field instruction of FIG. 39 in which src2 points to the ZeroReg.

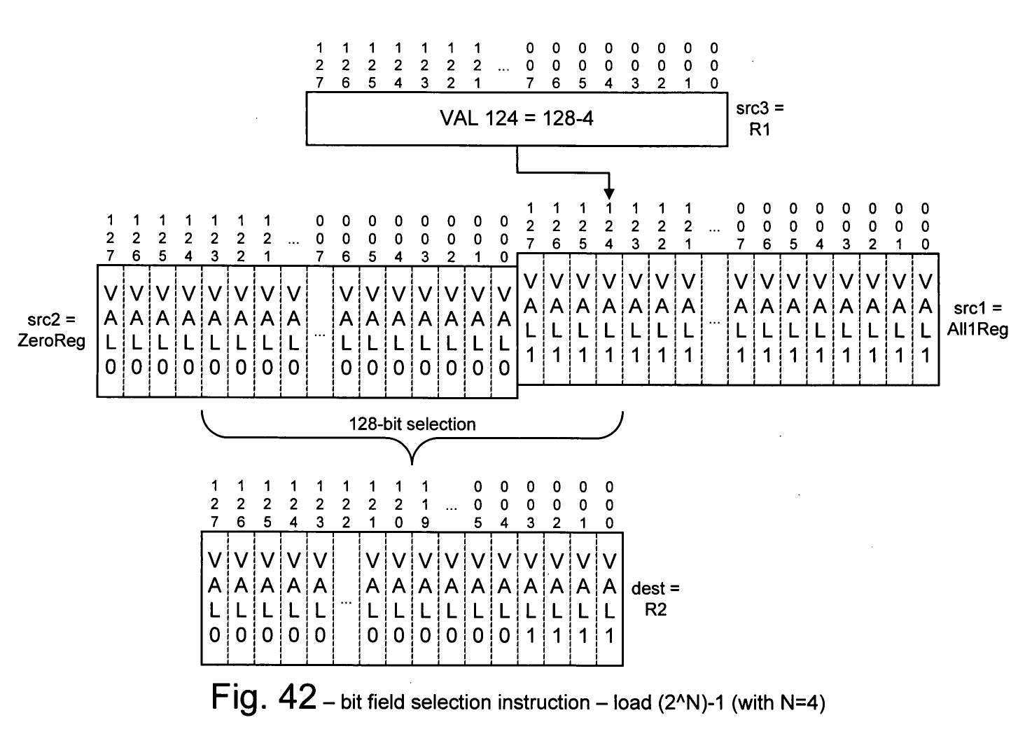

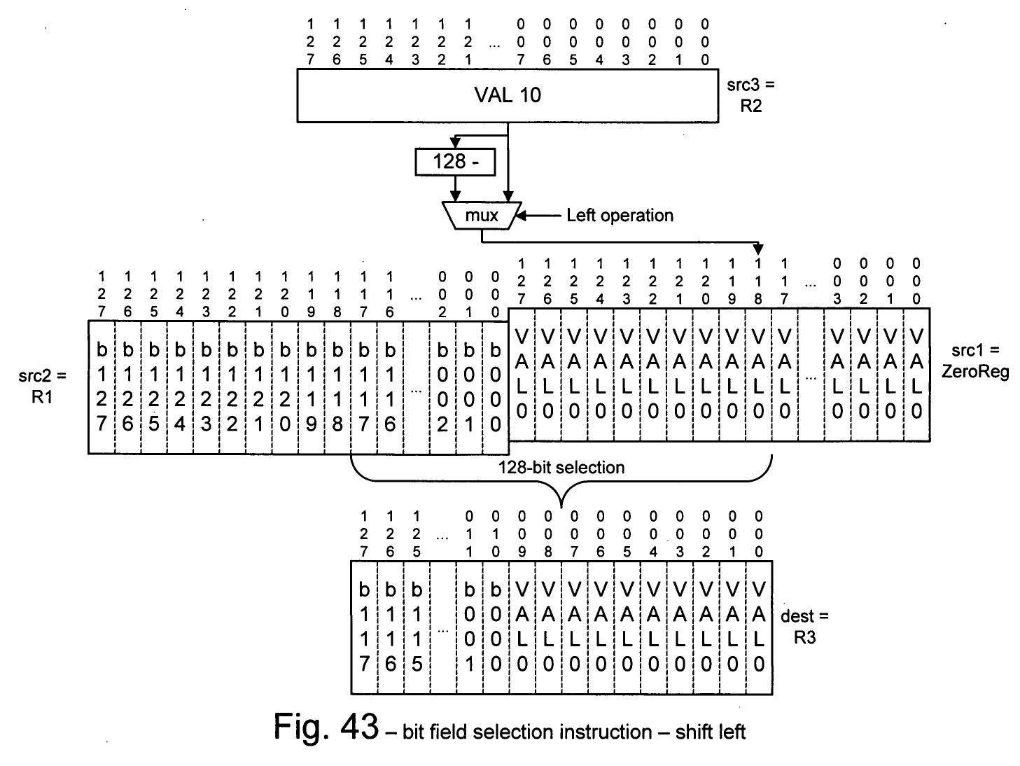

FIG. 42 illustrates the operation of the bit field selection instruction in performing a bit field selection in which both source operands src1 and src2 are pointed at fixed-content or constant registers, in this instance All1Reg and ZeroReg. Pointed thus, the operation performed is essentially a load (2ˆN)−1, where N is the value in R1 to which scr3 points.

FIG. 43 illustrates an alternative embodiment of the shift left operation, in which the processor includes hardware for assisting the bit field selection instruction in performing leftward operations. The first source src1 points at the ZeroReg and the second source src2 points at R1, as they did in FIG. 38. However, while in FIG. 38 the compiler had to put 128-N (where N is the shift count) into the register pointed at by src3, in FIG. 43 the hardware assist mechanism takes care of this, and the compiler is enabled to load the shift count (in this case 10) directly into the register R2 pointed at by src3.

A multiplexer is coupled to receive the value from the register R2 pointed at by src3, and also the output of a subtractor which subtracts that value from 128. The multiplexer is controlled by a signal which specifies whether the instruction is performing a leftward or a rightward operation. In some embodiments, this control signal is generated as a function of the opcode (not shown) of the instruction, specifically those bit(s) which indicate that it is a shift left. The destination register R3 is written with src2[(127−src3 ):0] and ZeroReg[127:(128−src3 )].

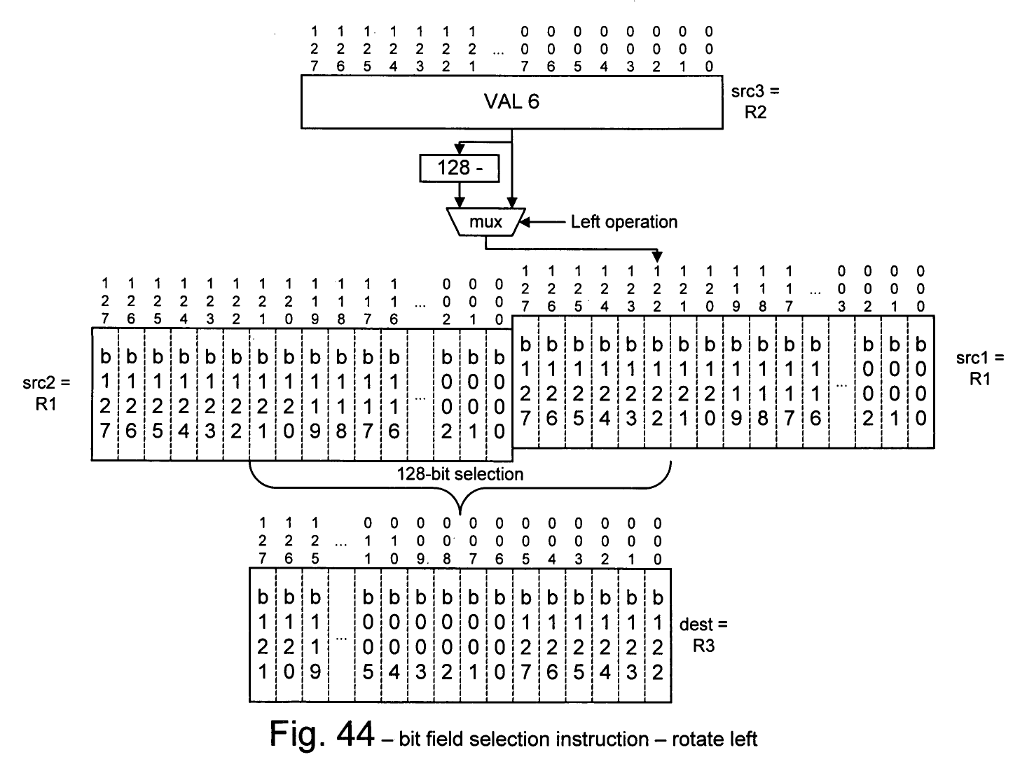

FIG. 44 similarly illustrates a rotate left operation being performed using the bit field selection instruction and the hardware assist mechanism. The difference being that both src1 and src2 are pointed at the value to be rotated.

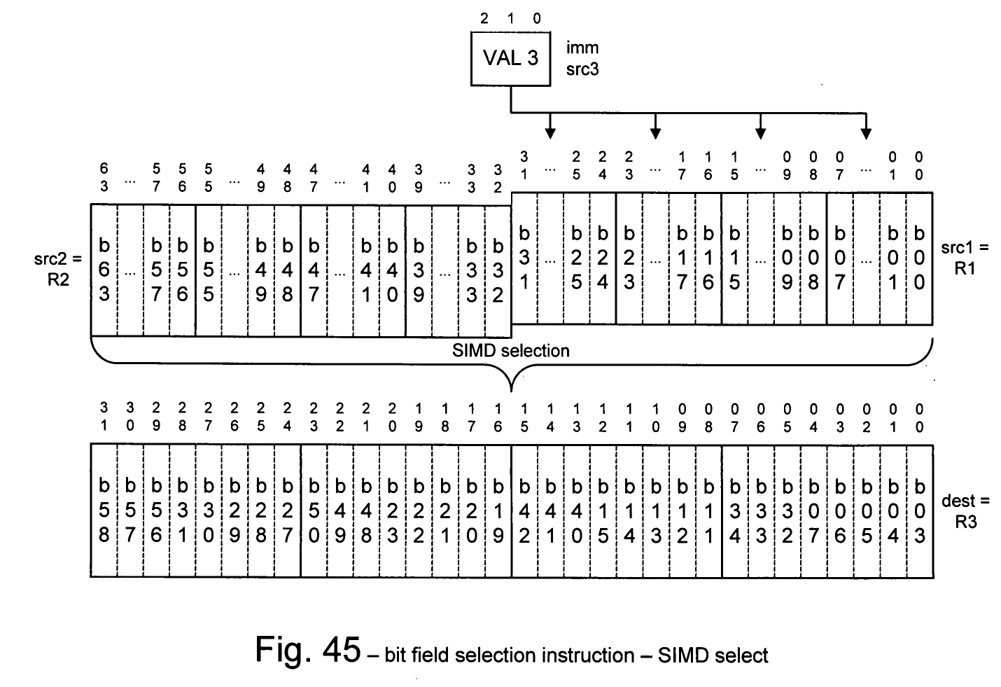

FIG. 45 illustrates the operation of a single instruction multiple data (SIMD) implementation of the bit field selection instruction. The instruction specifies a first SIMD source operation designator src1, a second SIMD source operand designator src2, and a SIMD destination designator dest, each of which points to, in the example shown, a respective 32-bit SIMD register which is treated as storing four 8-bit values or SIMD elements. The instruction includes a 3-bit immediate scr3whose value is used as an offset into each of the SIMD elements. In the example shown, scr3 contains the value 3, and thus points at bit 3 of each SIMD element.

The 8-bit first SIMD element of src1 and the 8-bit first SIMD element of src2 are treated as a 16-bit value. The bit field instruction selects an 8-bit field from that 16-bit value and writes it into the first 8-bit SIMD element of dest. In the example shown, this includes, from the LSB toward the MSB, b03 through b07 from src1 and b32 through b34 of src2. If scr3 had specified a value larger than 7, the bit field selection operation would have written low order dest bits from src2 and then “wrapped around” to continue picking higher order bits from src1.

The same operation is performed simultaneously for corresponding sets of the second, third, and fourth SIMD elements of the sources and destination, as shown.

### Conclusion

It is not necessary to provide the user with an exhaustive list detailing every possible way that the flexible permute operation can be used to perform other, more rigid data movement operations. Nor is it necessary to provide the user with an exhaustive list detailing every possible way in which bit-wise data manipulations can be combined with the flexible permute operation to perform bit-wise data movements in the absence of complex, dedicated hardware. After reading this disclosure and studying the examples given in the various drawings, the reader will appreciate these principles and understand how to apply them to any data movement operation that happens to be required in his application at hand. The invention has been discussed in terms of various implementations in which the smallest “course grain” data element is the 8-bit byte, but the invention is not so limited; in other implementations, the smallest course grain data element might be, for example, a 12-bit pixel value, or a 16-bit floating point value, or what have you. The smallest course grain data element can, regardless of its size, be referred to as a “base element” or an element having a “base size”. Rotates, shifts, shuffles, merges, explodes, rotates, shifts, permutes, and the like may collectively be termed “data rearrangement instructions”. Registers, memory locations, latches, gates, and the like may collectively be termed “data storage locations”.

The invention has been described with reference to its use in implementing a machine adapted for performing instructions such as rotate, shift, permute, pack, unpack, bit field selection, merge, expand, and so forth. It may also be used in performing other instructions, such as move, insert, and so forth. The invention may be used in a processor of any type of architecture, whether RISC, CISC, VLIW, or what have you. It may be used in processors that are microcoded, as well as those which are not. It may be used in processors which are primarily designed for digital signal processing, as well as those adapted for more general purpose use. It may be used in any particular type of system, such as embedded control systems, cell phones, personal digital assistants, computers, consumer electronic devices, automotive systems, and so forth. It may be used in a processor which is adapted to execute instructions from exactly one single ISA, or in a processor which is adapted to execute instructions from two or more ISAs.

Instructions may be encoded in a wide variety of manners. In some instances, each instruction field (e.g. opcode, first operand designator, second operand designator, destination designator, immediate data, and so forth) occupies a contiguous group of bits in the instruction. In other embodiments, the bits may be scattered and the designators interleaved with each other. In some, various ones of the designators may be implicit rather than explicit; for example, certain instructions may always use the src1 as the dest, overwriting src1; as another example, certain other instructions may always write to a predetermined dest such as R1.

While the invention has been described with reference to embodiments in which e.g. the scr3 value indicates an offset from the low order end of src1, in other embodiments the scr3 value could indicate an offset from the high order end of src2.

When one component is said to be adjacent another component, it should not be interpreted to mean that there is absolutely nothing between the two components, only that they are in the order indicated. The various features illustrated in the figures may be combined in many ways, and should not be interpreted as though limited to the specific embodiments in which they were explained and shown. Those skilled in the art having the benefit of this disclosure will appreciate that many other variations from the foregoing description and drawings may be made within the scope of the present invention. Indeed, the invention is not limited to the details described above. Rather, it is the following claims including any amendments thereto that define the scope of the invention.

In the following claims, designators such as “first” and “second” (e.g. in “first operand designator” and the like) are not intended to imply any particular order of their bit fields or bits within the instruction.

What is claimed is:

1. A method whereby a processor executes an instruction, the method comprising:
(a) extracting an N-bit contiguous bit field from,
high order bits of a first source operand designated by a first source operand designator of the instruction, and
low order bits of a second source operand designated by a second source operand designator of the instruction; and
(b) writing the N-bit contiguous bit field to a destination designated by a destination designator of the instruction;
wherein the first and second source operands are treated as a 2N-bit operand.

2. The method of claim 1 wherein:
the first source operand comprises a register exactly N bits wide;
the second source operand comprises a register exactly N bits wide; and
the destination comprises a register exactly N bits wide.

3. The method of claim 1 wherein:
the N-bit contiguous bit field is extracted from a position specified by a third source operand designated by a third source operand designator of the instruction.

4. The method of claim 3 wherein:
the third source operand specifies an offset as a number of bits from an end of the 2N-bit operand.

5. The method of claim 4 wherein:
the third source operand specifies the offset as a number of bits from a least significant bit end of the first source operand.

6. The method of claim 4 wherein:
the first source operand comprises a 128-bit register;
the second source operand comprises a 128-bit register; and
the destination comprises a 128-bit register.

7. The method of claim 1 wherein:
the first and second source operand designators designate a same source operand;
whereby the instruction accomplishes a rotate operation upon the source operand.

8. The method of claim 1 wherein:
the first and second source operand designators designate different source operands.

9. The method of claim 8 wherein:
the N-bit contiguous bit field is extracted from a position specified by a third source operand designated by a third source operand designator of the instruction;
the third source operand specifies a position of a least significant bit of the N-bit contiguous bit field.

10. The method of claim 8 wherein:
the first source operand designator designates a first source operand containing all zeroes;
whereby the instruction accomplishes a shift left operation upon the second source operand.

11. The method of claim 10 wherein:
the first source operand comprises a dedicated ZeroReg register which always contains zeroes during operation of the processor.

12. The method of claim 10 wherein:
the N-bit contiguous bit field is extracted from a position specified by a third source operand designated by a third source operand designator of the instruction;
wherein the first and second source operands each comprise respective N-bit registers;
wherein the third source operand contains a value N−X; and
wherein X comprises a shift count of the shift left operation.

13. The method of claim 8 wherein:
the second source operand designator designates a second source operand containing all zeroes;
whereby the instruction accomplishes a shift right operation upon the first source operand.

14. The method of claim 13 wherein:
the second source operand comprises a dedicated ZeroReg register which always contains zeroes during operation of the processor.

15. The method of claim 8 wherein:
all bits of the second source operand contain a same binary value as a most significant bit of the first source operand;
whereby the instruction accomplishes an arithmetic shift right of the first source operand.

16. The method of claim 15 wherein:
the second source operand comprises a dedicates All1Reg register which always contains ones during operation of the processor.

17. The method of claim 8 wherein:
the first source operand comprises a first fixed content register which always contains a first fixed content during operation of the processor; and
the second source operand comprises a second fixed content register which always contains a second fixed content during operation of the processor.

18. The method of claim 1 wherein:
the first and second source operands each comprises a respective N-bit register;
a third source operand of the instruction identifies an offset X; and the method further comprises
if the instruction is for performing a leftward operation, using one of X and N−X as an offset from an end of the 2N-bit operand from which the bit field is selected; and
if the instruction is for performing a rightward operation, using the other of X and N−X as an offset from an end of the 2N-bit operand from which the bit field is selected.

19. The method of claim 18 wherein:
the third source operand is designated by a third source operand designator of the instruction and contains the offset X as an offset from a least significant bit end of the 2N-bit register;
if the instruction is for performing a leftward operation, subtracting X from N to generate an offset Y from a most significant bit end of the first source operand.

20. The method of claim 19 further comprising:
subtracting X from N to generate a X−N result regardless of whether the instruction is for performing a leftward operation or a rightward operation; and
selecting between the X−N result and X, depending upon whether the instruction is for performing a leftward operation or a rightward operation, respectively.

21. The method of claim 19 further comprising:
during a single execution of the instruction, performing a plurality of the extracting and the writing in SIMD manner.

22. A method whereby a processor having a plurality of N-bit registers executes an instruction, the method comprising:
decoding an opcode of the instruction;
in response to decoding the opcode, determining that the instruction is a bit field selection instruction;
copying Z highest-order bits from a first N-bit source register designated by a first source operand designator of the instruction into Z low-order bits of an N-bit destination register designated by a destination designator of the instruction;
copying Y lowest-order bits from a second N-bit source register designated by a second source operand designator of the instruction into Y high-order bits of the N-bit destination register;
wherein Y+Z=N; and
wherein the instruction specifies which Y+Z bit field to copy into the destination register.

23. The method of claim 22 wherein:
the instruction specifies the Y+Z bit field as an offset X from an end of one of the first and second source registers.

24. The method of claim 23 wherein:
X specifies an offset from a low order bit end of the first source register.

25. The method of claim 23 wherein:
the instruction expressly specifies X.

26. The method of claim 23 wherein:
the instruction expressly specifies X in a third N-bit source operand register designated by a third source operand designator in the instruction.

27. The method of claim 26 wherein:
for rightward operations, the third N-bit source operand register holds X; and
for leftward operations, the third N-bit source operand register holds N−X.

28. The method of claim 23 wherein:
by the first and second source operand identifiers designating a same N-bit register, the instruction performs a rotate operation.

29. The method of claim 23 wherein:
by one of the first and second source operand identifiers designating a register holding data, and the other of the first and second source operand identifiers designating a register holding N bits of a same value, the instruction performs a shift operation.

30. The method of claim 29 wherein:
by the first source operand identifier designating a register holding all zeroes and the second source operand identifier designating the register holding the data, the instruction performs a shift left operation.

31. The method of claim 29 wherein:
by the second source operand identifier designating a register holding all zeroes and the first source operand identifier designating the register holding the data, the instruction performs a logical shift right operation.

32. The method of claim 29 wherein:
by the second source operand identifier designating a register holding N bits having a same value as a highest order bit of the register holding the data, and the first source operand identifier designating the register holding the data, the instruction performs an arithmetic shift right operation.

33. The method of claim 22 wherein:
copying Z bits and copying Y bits each comprises a SIMD operation.
